(19) United States
(12) Patent Application Publication
(10) Pub. No.: US 2019/0044548 A1
(43) Pub. Date: Feb. 7, 2019

(54) FRONT END MODULE FOR CARRIER AGGREGATION OPERATION

(71) Applicant: SNAPTRACK, INC., San Diego, CA (US)

(72) Inventor: Stephan FREISLEBEN, Neubiberg (DE)

(21) Appl. No.: 16/074,723

(22) PCT Filed: Dec. 1, 2016
(86) PCT No.: PCT/EP2016/079483

§ 371 Date: Aug. 1, 2018

(30) Foreign Application Priority Data
Feb. 5, 2016 (DE) 10 2016 102 073.7

(51) Int. Cl. H04B 1/00; H03H 9/72; H04L 5/14

(52) U.S. Cl. CPC H04B 1/0057; H04L 5/14; H03H 9/725; H04B 1/006

(57) ABSTRACT

For improved band separation in a front-end module, it is proposed to extract an extractor band using an extractor arrangement comprising a notch filter and an extractor path including bandpass filters. The front-end module further has a diplexer that separates a first and a second frequency range with a diplexer spacing. The extractor band lies between the two frequency ranges such that it does not overlap with any of the two frequency ranges. In this way, the distance between the two frequency ranges is increased beyond the actual diplexer spacing.

To increase the data transfer rate in mobile radio systems, operational procedures are defined in which a call connection or data transfer takes place synchronously within at least two different frequency bands.

In mobile communications, such operating procedures are also known by the name of carrier aggregation mode. These use at least three FDD frequency bands, of which at least two are receive bands/RX bands which are optionally combined with one or more transmit bands/TX bands. In the case of TDD systems, carrier aggregation is already possible with two TDD bands. For this purpose, the corresponding signal paths, in which filters assigned to the bands and, in particular, duplexers are arranged, are connected in parallel to one or more antennas.

In particular, solutions with only one antenna here require a good signal separation, with suitable multiplexers. The quality of frequency separation in the case of parallel operation in multiple bands increases with the frequency spacing of the bands which are to be separated from each other. Signal separation is adversely affected by narrow band spacings and also by high multiplex levels—in other words, multiplexers that separate more than two bands from each other. This can usually be achieved only with filters and duplexers of high-frequency precision and a complex matching circuit.

For a solution with two antennas, at least one cellular quadplexer is required for a carrier aggregation with three receive bands. The disadvantage of this solution is that metallic housings are problematic for mobile devices with multiple antennas.

For the solution with one antenna, a front-end module is required which includes at least one cellular hexaplexer. However, a hexaplexer has a complex structure, which is associated with high costs.

Another solution for carrier aggregation operation with only one antenna requires a triplexer that separates, for example, the band ranges of LB (low-band), MB (mid-band) and HB (high-band) from each other. The problem with this solution, however, is the narrow gap between the mid-band, which ends at 2200 MHz, and the high-band, which starts at 2300 MHz. It is therefore difficult to create cost-effective solutions of highly-integrated triplexers, such as those realized in LTCC technology, for this task.

In the carrier aggregation method of operation, in which multiple receive channels are connected, it is important that the signal paths do not block each other or that the signals do not leak into the respective other band, which would result in higher power losses and hence a greater insertion loss. The situation is similar for a carrier aggregation mode, in which multiple transmit bands are operated in parallel for a communication link.

Another problem is that a great number of band combinations for the carrier aggregation mode are under discussion, which may have to be implemented in parallel in corresponding front-end modules. This makes band separation even more difficult.

The aim of the present invention is to provide a front-end module which has been improved for a carrier aggregation operation and with which band separation is possible using simpler means and with lower losses.

This aim is achieved according to the invention by a front-end module according to claim 1. Advantageous embodiments of the invention will become apparent from the dependent claims.

The basic idea of the invention is—in a first signal path, which is coupled to an antenna connection—to provide a diplexer which separates a first and a second frequency range from each other and, at the output end, assigns them to a first and a second sub-path respectively. Due to its design, the diplexer has a first diplexer spacing. By diplexer spacing is meant the minimum distance between two signals receivable at the diplexer input and which, at the output of the diplexer, can be separated from each other with low attenuation and which thus can be assigned to different sub-paths.

In addition, a notch filter coupled to the diplexer is provided which has a first stopband. According to the invention, the notch filter is so designed that its stopband is arranged between the first and the second frequency ranges, but does not overlap either of the two adjacent frequency bands. In this way, it is possible to make the diplexer impassable to signals within the stopband. In this case, the mutually-facing flanks of the two passbands of the diplexer are steepened, and more sharply limited passband limits are thus obtained.

A first extractor path is connected to a node arranged in the signal path between antenna connection and first notch filter. Signals falling within the stopband can be extracted in this way from the signal line via the first extractor path.

In addition, a bandpass filter is arranged in the extractor path, which is passable for the extractor band, but which attenuates other frequencies. Notch filter and extractor path together form an extractor arrangement with which signals falling within the extractor band can be extracted from the signal path.

The proposed front-end module has the advantage that the diplexers can be realized with a relatively high diplexer spacing, which is technically easier than is possible with a smaller diplexer spacing. Here, signals lying between the first and second frequency ranges are not lost, since they can be coupled out via the extractor path. Diplexer and extractor arrangement together form a triplexer, which can separate an extractor band and a first and a second frequency range from each other.

The diplexer of the front-end module according to the invention can therefore be realized in a simple manner in an LTCC or a laminate as a combination of a high-pass filter and a low-pass filter. It is also possible, of course, for it to take the form of a discrete filter made up of SMD inductors and SMD capacitors.

According to one embodiment, in the first signal path between the first antenna connection and the notch filter, a second diplexer or a higher multiplexer is arranged which separates at least a third frequency range from the first signal path and routes it into a third or even a further sub-path. The front-end module can thus, via the three sub-paths, cleanly separate three frequency ranges from each other and, via the extractor path, an extractor band. It is thus possible to operate the three frequency ranges and the extractor band independently of each other and also in parallel, without mutual interference taking place. The frequency ranges and the extractor band can also be isolated from each other, with minimal losses.

According to an exemplary embodiment, the stopband of the notch filter or the extractor band is designed such that it fully overlaps the RX band of band 1 and/or band 4 and/or band 66. Since the Rx band of band 66 occupies exactly the same frequency range as band 65, in accordance with this embodiment, the Rx band of band 66 naturally lies within the stopband of the notch filter. A filter for band 4 Rx can here, and in all other embodiments, be designed so that it also includes, in addition, the broader bands, band 1 Rx, or even band 65/66 Rx as well. All four bands are located in the same narrow frequency band between 2110 MHz and 2200 MHz. The bandpass filter in the extractor path is, correspondingly, designed for the RX band of band 1 and/or band 4 and/or band 65/66. It also applies below that any mention of the Rx band of band 66 is at the same time to include the Rx band of band 65, and that a filter usable for band 66 RX can always be used for band 65 RX as well.

For the first diplexer, it will suffice when the first frequency range includes frequencies up to 1995 MHz, or alternatively—with the inclusion of band 34—frequencies up to 2025 MHz. Correspondingly, the second frequency range can then include frequencies ≥2300 MHz.

For a front-end module without an extractor arrangement and which includes the RX bands of band 1 and/or band 4 and/or band 66, without the invention, a diplexer with a diplexer spacing of 100 MHz would be required, ranging from 2200 MHz to 2300 MHz. Since the above-mentioned frequencies of RX bands 1, 4, and 66 are routed out via the extractor path, a diplexer spacing of 305 MHz (or 275 MHz) is sufficient for the diplexer, viz., from 1995 MHz to 2300 MHz (or from 2025 MHz to 2300 MHz). This makes technical realization of the diplexer in LTCC or laminate technology easier. A realization in any other technology is, of course, also possible, which, for example, includes discrete filters using SMD components.

According to a further embodiment, the extractor band is designed for the extraction of the frequencies of band 30 (Rx and Tx) and/or band 40, which is a TDD band. Accordingly, the stopband of the notch filter is located such that it fully overlaps the two narrow RX and Tx bands of band 30 and/or the broader band 40. All these bands are located in the frequency range between 2300 and 2400 MHz, partially overlapping each other. Accordingly, the bandpass filter in the extractor path can be designed for the RX band of band 30 and/or band 40. It also applies to all other exemplary embodiments that a filter for band 40 is also at the same time designed for the frequencies of band 30 Rx and Tx. Conversely, a band 30 filter can, by means of a correspondingly broader band, be designed, in addition, for band 40 as well. By assigning to the extractor path the frequencies for the RX bands of band 30 and/or band 40, it is possible to extend the diplexer spacing to a range of 2200 MHz to 2496 MHz. Without extraction of the RX frequencies of band 30 and/or band 40, a diplexer would be required with a diplexer spacing of only 100 MHz, which would need to be located in the range of 2200 MHz to 2300 MHz. Here, too, the high diplexer spacing makes a technologically simple technical realization of the diplexer possible.

In a further embodiment of the invention, a second notch filter is arranged in the first signal path or in one of the sub-paths selected from the first, second, and third sub-paths. This has a second stopband and, together with a second extractor path in which a second bandpass filter is arranged, forms a second extractor arrangement. The passband of the second bandpass filter corresponds to a second extractor band. The second stopband and second extractor band overlap at least partially. In this way, it is possible to extract the two, possibly narrow-band frequency bands, regardless of the diplexers, so that the remaining bands can be better separated and isolated from each other.

The second extractor band advantageously corresponds to a pure Rx signal, which can be filtered out particularly well via an extractor arrangement. This is due to the high reflectivity of the notch filter for frequencies lying within the stopband. These frequencies can pass the extractor arrangement only via the extractor path, and not by the path in which the notch filter is arranged. The extraction therefore succeeds, with a high level of efficiency and low attenuation.

In one embodiment, two extractor arrangements are provided in the front-end module which are designed for extracting one extractor band in each case. The first extractor band includes the RX band of band 66 and/or band 1. The second extractor band is designed for frequencies which are selected from GNSS, WLAN 2.4, band 40, band 30 LX, band 32 RX, and LMB. LMD stands for “lower mid-band” and includes frequencies from 1425 MHz to 1511 MHz. With such a front-end module, it is possible to extract the frequencies of the two extractor bands from the entire frequency spectrum.

An extractor arrangement arranged in a signal path only marginally increases the insertion loss in the signal path. It is therefore possible to provide a greater number of extractor arrangements, without the insertion loss in the remaining frequency ranges being unacceptably increased.

According to one embodiment of the invention, three extractor arrangements are therefore provided, which are designed to extract three different extractor bands together. The first extractor band here includes the RX band of band 66 and/or the RX band of band 1. The second and the third extractor bands are designed for frequencies which are selected independently of each other from GNSS, WLAN 2.4, band 40 RX, band 30 RX, band 32 RX, and LMB.

In accordance with one embodiment of the invention, the filters used for the extractor arrangements, i.e., each notch filter and each of the bandpass filters arranged in one of the extractor paths, comprise micro-acoustic resonators which realize a SAW filter, a temperature-compensated SAW filter, or a BAW filter. By a temperature-compensated SAW filter is meant a SAW filter which has a temperature coefficient of the frequency reduced by using a compensation layer.

A temperature-compensated SAW filter has, for example, a SiO₂ layer over the electrode structures, whose thickness measures about 20 to 30% of the acoustic wavelength λ propagable in the material in question.

The bandpass filter in the extractor paths can, for example, comprise a ladder-type arrangement of micro-acoustic resonators or DMS tracks.

The notch filter can also be designed as a ladder-type arrangement, wherein the parallel or serial resonators can be partially or entirely replaced by coils. It is possible, however, in each case to use a single resonator as notch filter, wherein the stopband of such a notch filter formed by a micro-acoustic resonator lies in the range of the anti-frequency of the resonator.

The diplexers used in the front-end module according to the invention in each case comprise a low-pass filter and a high-pass filter. It is also possible for one or two of the filters of the diplexer to be designed as bandpass filters. The filters can in each case be composed of L and C elements. Here, it is possible to integrate the L and C elements in an LTCC ceramic or a laminate—for example, in the form of conductor tracks and structured metallizations. It is, however, also possible for the filters of the diplexer to be composed of discrete L and C elements, which are mounted together on a carrier and, here again, represent an independently marketable component.

According to a further embodiment, at least one of the extractor arrangements is bypassed with a bypass path, in which a switch for opening or closing the bypass path is arranged. It is thus possible to prevent the extraction of the extraction band by opening the switch in the bypass path. Since the notch filter is also bypassed in this way, signals in the range of the extraction band can pass the signal path unreflected or unattenuated. In this way, it is possible to avoid the increase in impedance in the signal path arising from the extractor arrangement, which has to be accepted when access to the extraction band is not necessary. The bypass path can always then be opened.

Here, it is possible to provide each of the extractor arrangements of the front-end module with such a bypass path, which can be unlocked or locked by means of a respective switch.

In a further embodiment of the invention, each one of the sub-paths is connected to the input of an antenna switch. Here, a separate antenna switch can be provided for each sub-path. It is, however, also possible to connect all sub-paths to a common antenna switch. Via an appropriate switch position of the antenna switch, the output of the antenna switch is connected to a band channel in which a filter element for the particular band assigned to the band channel is arranged. Such a filter element usually includes a duplexer, i.e., whenever the band uses an FDD method and is not a pure receiver band.

In one embodiment, a novel mixed duplexer is used that combines an RX filter for any first band and a TX filter for any second and different band. In this way, it is possible to guide RX and TX frequencies of a band through various filter elements which are arranged in different paths or band channels.

If, for example, the extractor band includes the RX frequencies of the second band, it is possible to extract the RX frequencies of the second band via the extractor path, but the Tx frequencies, in contrast, via a mixed duplexer that is connected to the output of the antenna switch. A pure duplexer, which comprises a TX filter and a corresponding RX filter for the first band, is accordingly provided at a different output of the antenna switch. In this way, it is possible to filter the RX frequencies of the first band, optionally, via the mixed duplexer or via the pure duplexer. The RX signal of the second band is received exclusively via the extractor path. As a result, the Rx bands of the first and second bands are always available at the same time, as is required for downlink carrier aggregation. In the following, carrier aggregation is always to be understood as meaning downlink 5-carrier aggregation, unless an example expressly refers to uplink carrier aggregation.

In a specific embodiment, in a mixed duplexer, a TX filter for band 1 is combined with an RX filter for band 3, or a TX filter for band 4 is combined with an RX filter for band 2. Parallel to this, an extractor band, with a band 4 RX filter or with a band 1 RX filter or a band 65/66 RX filter, is provided as bandpass filter. A further possible embodiment for a mixed duplexer combines band 3 Rx and band 65 Tx.

According to one embodiment, a mixed duplexer is provided which combines a TX Filter for band 1 with an RX filter of band 3, or a TX Filter for band 65 with an RX filter of band 3, or a TX Filter for band 4 with an RX filter of band 2, or a TX Filter for band 4 with an RX filter of band 25, or a TX Filter for band 66 with an RX filter of band 2, or a TX Filter for band 66 with an RX filter of band 25. Such a mixed duplexer is combined with an extractor arrangement, in which the extractor band is designed for RX frequencies of band 4 or for RX frequencies of band 1 or for RX frequencies of band 65/66. In addition, pure duplexers are envisaged which combine the Rx band of the above-listed mixed duplexers with the corresponding Tx band and can be selected from the duplexers for B3-Tx/B3-Rx, B2-Tx/B2-Rx and B25-Tx and B25-Rx.

In a specific embodiment, the output of the antenna switch can, optionally, be connected to a triplexer or a duplexer via the corresponding switch positions. The first triplexer takes the form of a mixed triplexer and comprises a TX filter for band 1, an RX Filter for band 3, and an RX filter for band 32. Alternatively, the first triplexer comprises a TX filter for band 65, an RX filter for band 3, and an RX filter for band 32. Another triplexer comprises a TX filter for band 3, an RX filter for band 3, and an RX filter for band 32. The RX bands still missing in the mixed triplexer, which are assigned to the Tx filters already present there, are filtered out or extracted via the extractor arrangements or the corresponding extractor paths. Accordingly, an extractor arrangement comprises an RX filter for band 4 or an RX filter for band 1 or an RX filter for band 65/66.

Such a mixed triplexer is advantageously combined with a mixed duplexer that is connected to another output of the antenna switch and comprises a TX filter for band 1 and an RX filter for band 11 or for band 21 Rx—the band directly adjacent to band 11. It therefore makes sense to design all the corresponding Rx filters for band 11 or band 21 with enough width to be able to serve both bands. Alternatively, a TX filter for band 1 is combined with an RX filter for band 11.

In a further embodiment, the mixed duplexer can comprise a TX filter for band 1 or 65 and an RX filter for band 21. Band 1 Tx is completely contained in the broader band 65 Tx, so that band 1 Tx can always be served by a band 65 Tx Filter as well. RX filters in an extractor band are accordingly assigned to this mixed duplexer, e.g., an RX filter for band 4, band 1 or band 65. Furthermore, in this case, another pure duplexer for band 11 or band 21 is provided in the front-end module. In this way, it is possible to filter RX bands for band 11 or band 21, optionally, via the pure duplexer or via the mixed duplexer.

In an alternative embodiment, the output of the antenna switch can be connected to a triplexer or a duplexer via a corresponding switch position. The triplexer may include, for example, a filter combination of a TX filter for band 1 or 65/66, a TX filter for band 3, and an RX filter for band 3. Alternatively, the triplexer may include a filter combination of a TX filter for band 2 or band 25, whose bands have almost the same coverage, an RX filter for band 4 or band 65/66, and an RX filter for band 2 or band 25. For this embodiment, an extractor band is assigned to the RX band of band 4 or to the RX band of band 1 or to the RX band of band 66. In this embodiment, too, duplex operation for the respective band (band 1, band 4, or band 66) takes place via two separate filters and hence on two separate paths, one of which is the extractor path. This embodiment can also be used for uplink carrier aggregation. It is generally true of this and other embodiments that Rx and Tx filters for band 25 automatically include band 2, or that a band 2 filter can be configured in a simple manner to cover band 25 as well.

In yet another embodiment, the output of the antenna switch can be connected via a corresponding switch position to a triplexer and/or a duplexer and/or a quadplexer. Here, the quadplexer can include a filter combination for band 1 TX or 65 TX, band 3 TX, band 3 RX, and band 32 RX. An extractor band is, accordingly, assigned to the RX band of band 4, band 1, or band 65/66. Duplex operation for band 1, band 4, or band 66 can then take place via different paths, wherein one of the paths is an extractor path. This embodiment, too, supports uplink carrier aggregation.

In further embodiments, the front-end module may comprise a pure receive path connectable to a diversity antenna. Furthermore, an extractor arrangement is also provided in the pure receive path, which branches off an extractor path. The corresponding extractor band is here assigned to the RX band of band 4, band 1, or band 66. Furthermore, a diplexer is arranged in the pure receive path which splits the pure receive path into two pure receive sub-paths, which are in each case assigned to a mid-band and a high-band range.

Here, a mixed diversity diplexer is arranged in the receive sub-path for mid-band, which has a filter combination for band 3 RX/band 21 RX or for band 3 RX/band 32 RX. In this way, it is possible, even in the pure diversity receive path, to separate a plurality of different receive bands in a simple way, wherein the diversity diplexer required for this can be realized in a simple way with a relatively high diplexer spacing, without band separation suffering thereby.

Between the diversity antenna and the extractor arrangement, a further diplexer, triplexer, or quadplexer can be arranged which branches off from the pure receive path a second sub-path for the low-band range. In this way, up to 5 receive sub-paths can be separated, which cover the low-band, the mid-band, the high-band, the ultra-high-band, and the 5 GHz ranges.

In a further development of the diversity path, a pure receive path is connected to the diversity antenna. An extractor arrangement branches off from the pure receive path an extractor path whose extractor band is assigned to the RX band of band 4, band 1, or band 65/66. Furthermore, a diplexer is arranged in the pure receive path which splits the pure receive path into two pure receive sub-paths, which are in each case assigned to a mid-band and a high-band range. Here, in the receive sub-path for mid-band, a mixed diversity triplexer is arranged which has a filter combination for the RX band of band 32, the RX band of band 21, and the RX band of band 3.

According to a further embodiment, two extractor arrangements are provided which are designed to extract one extractor band in each case. The first extractor band here includes band 30 RX and/or band 40. The second extractor band is designed for frequencies which are selected from Galileo, Beidou, Glonass or GPS (GNSS), WLAN 2.4, band 40, band 65/66 RX, band 32 RX, and LMB. Here, LMB covers frequencies of 1425 MHz to 1511 MHz.

The invention will be explained in greater detail below with reference to exemplary embodiments and the associated figures. The figures are partly schematic and, in most cases, show only partial structures of much more extensive arrangements or front-end circuits.

Shown are:

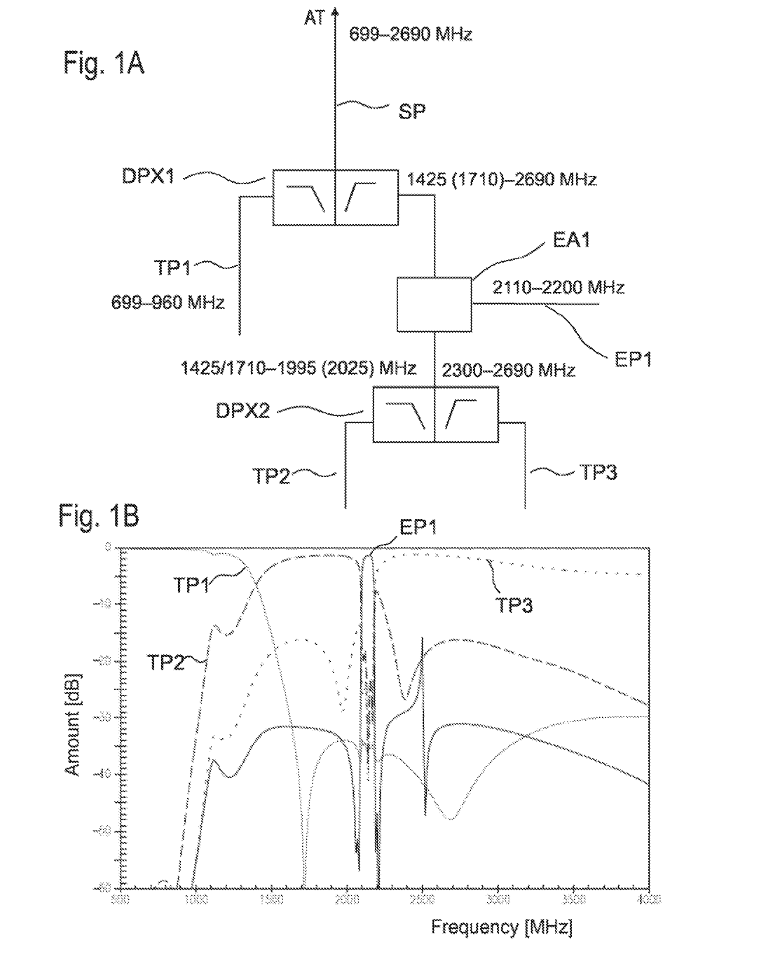

FIG. 1A a first front-end module according to the invention in schematic representation,

FIG. 1B the passband characteristics between the antenna connection and the various sub-paths as determined in the arrangement in FIG. 1A,

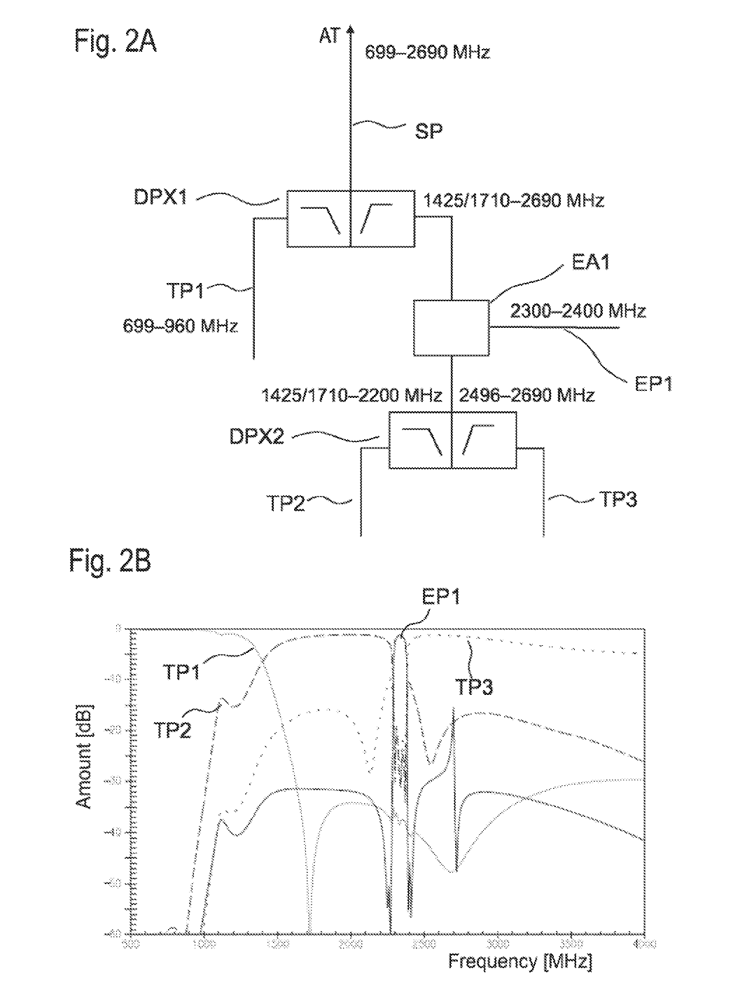

FIG. 2A a second exemplary embodiment of a front-end module,

FIG. 2B the passband characteristics between the antenna connection and the various sub-paths as determined in the arrangement in FIG. 2A,

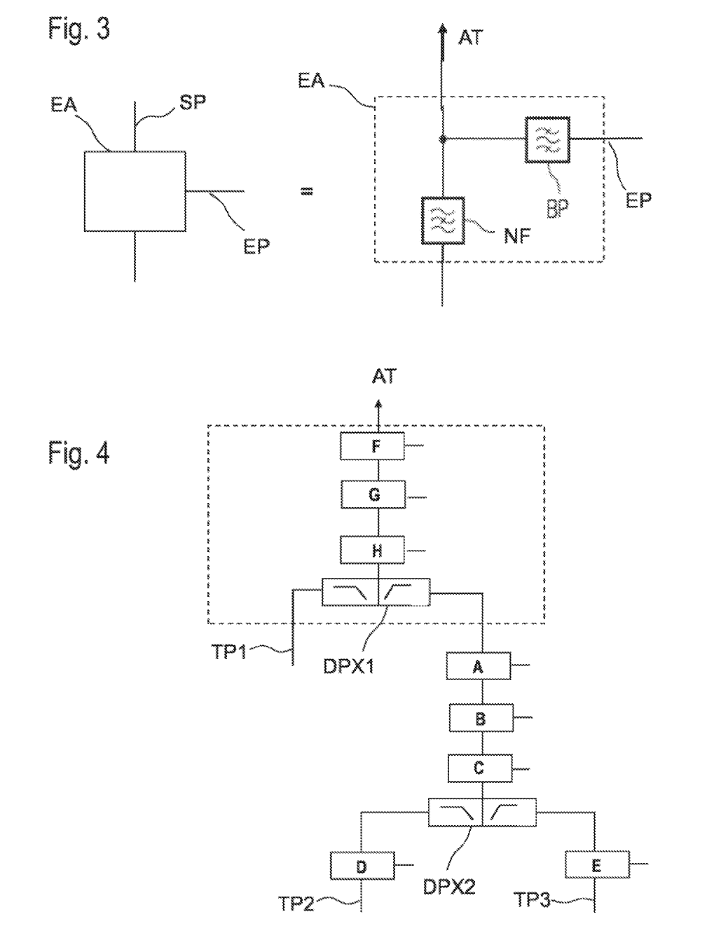

FIG. 3 an extractor arrangement as used in the front-end module according to the invention,

FIG. 4 various arrangement possibilities A through H of an extractor arrangement in a front-end module according to the invention,

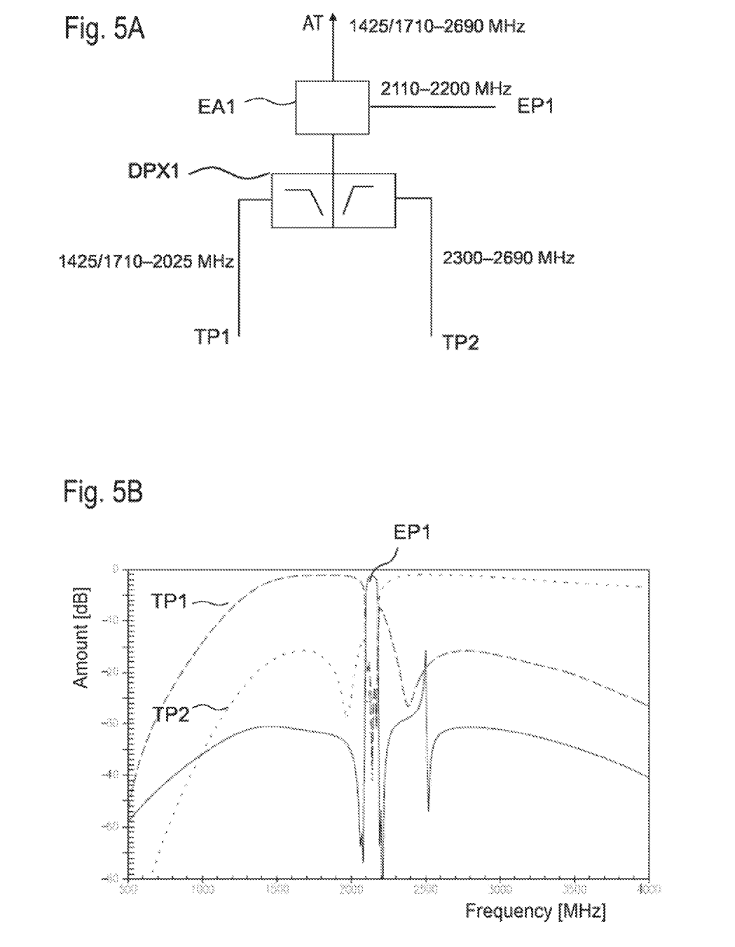

FIG. 5A a simple exemplary embodiment in schematic representation,

FIG. 5B the passband characteristics for the two sub-paths and the extraction path of the arrangement shown in FIG. 5A,

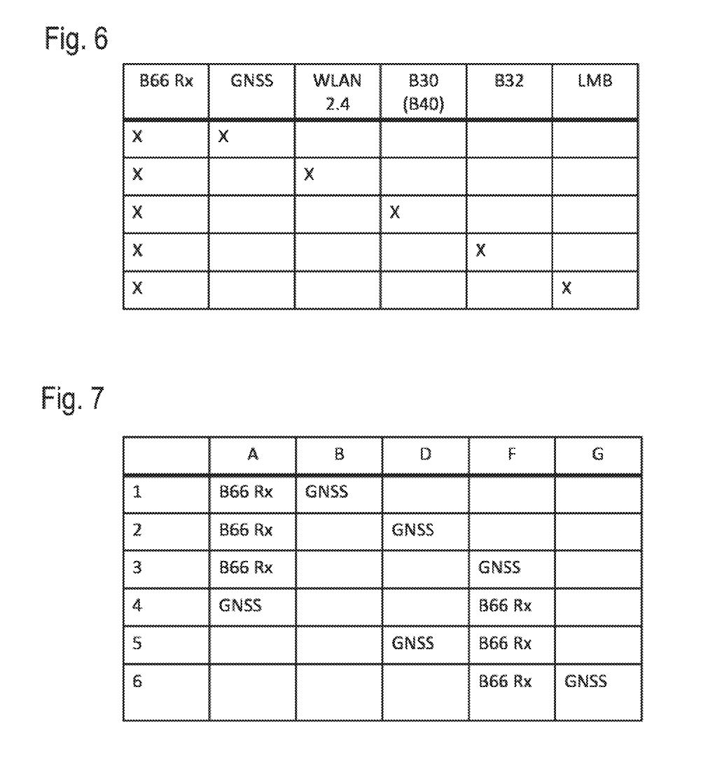

FIG. 6 a table with combinations of, in each case, two bands, each of which can be extracted by means of different extractor arrangements from the signal path of a front-end module according to the invention,

FIG. 7 shows by way of example how the two extraction arrangements can be distributed over the various positions A through G within a front-end module according to FIG. 4,

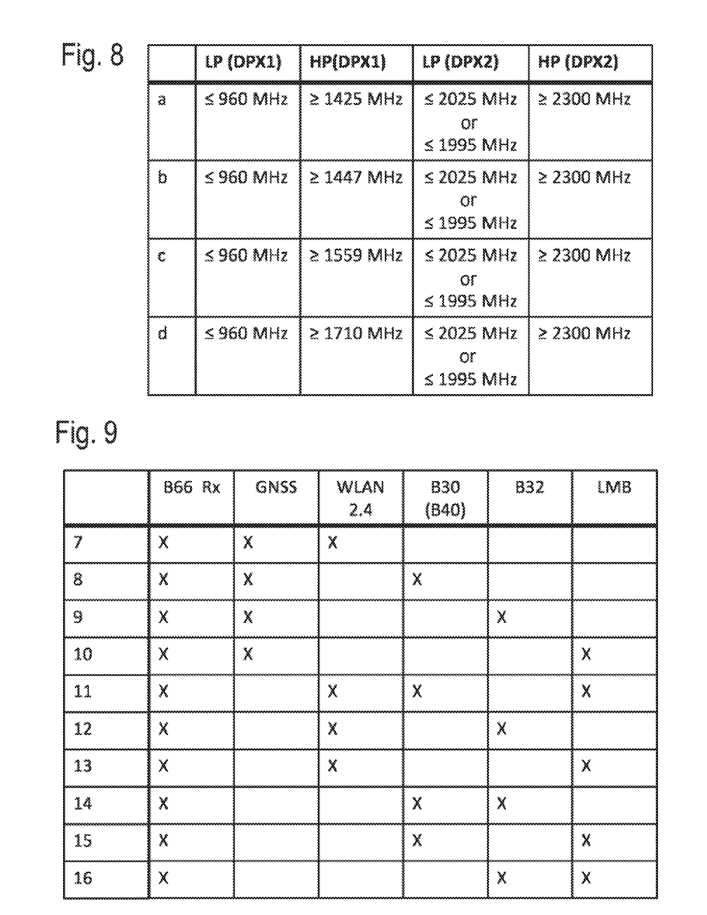

FIG. 8 shows possible passbands for two diplexers that can be used in a front-end module according to the invention,

FIG. 9 shows possible combinations of three bands, each of which can be extracted from the signal path by means of different extractor arrangements in a module according to the invention,

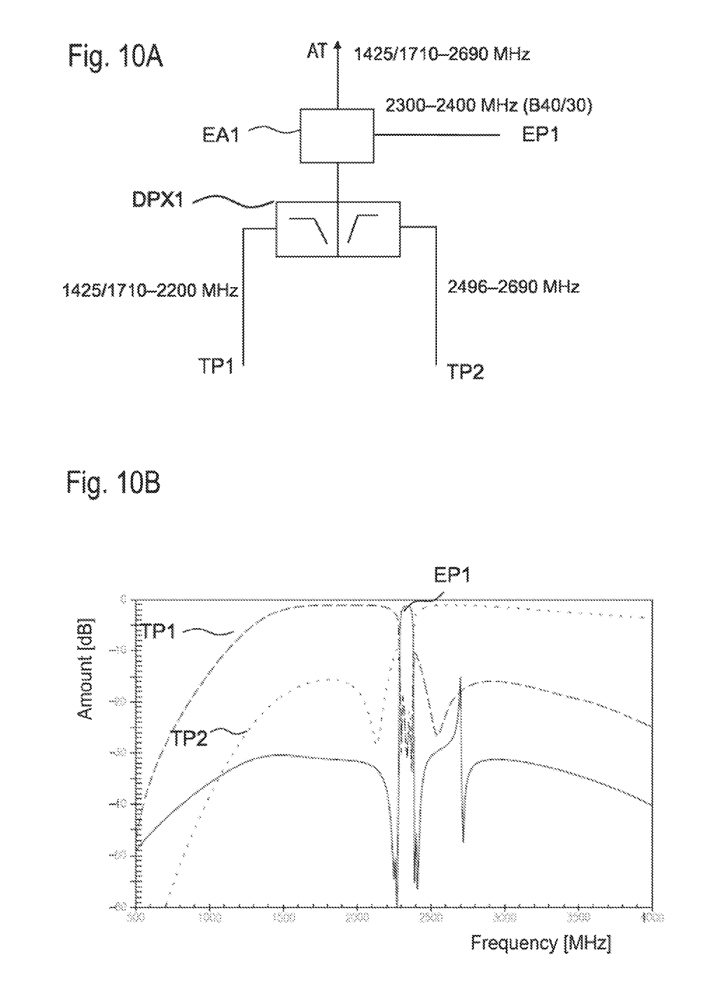

FIG. 10A shows a further simple exemplary embodiment in a schematic representation,

FIG. 10B shows the passband characteristics for the two sub-paths and the extraction path of the arrangement shown in FIG. 10A,

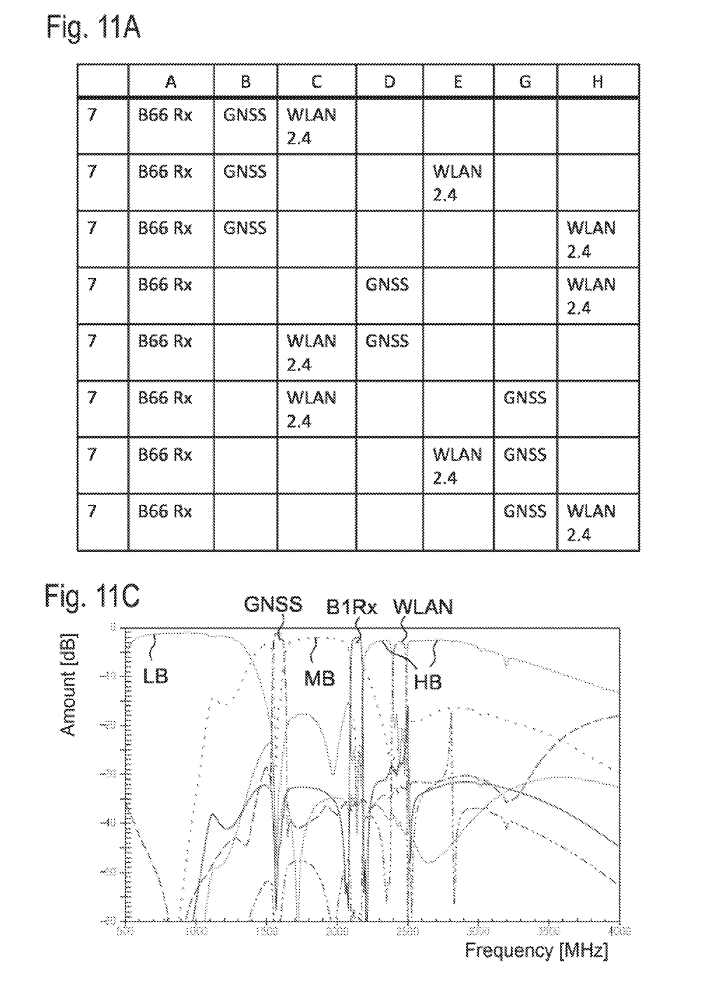

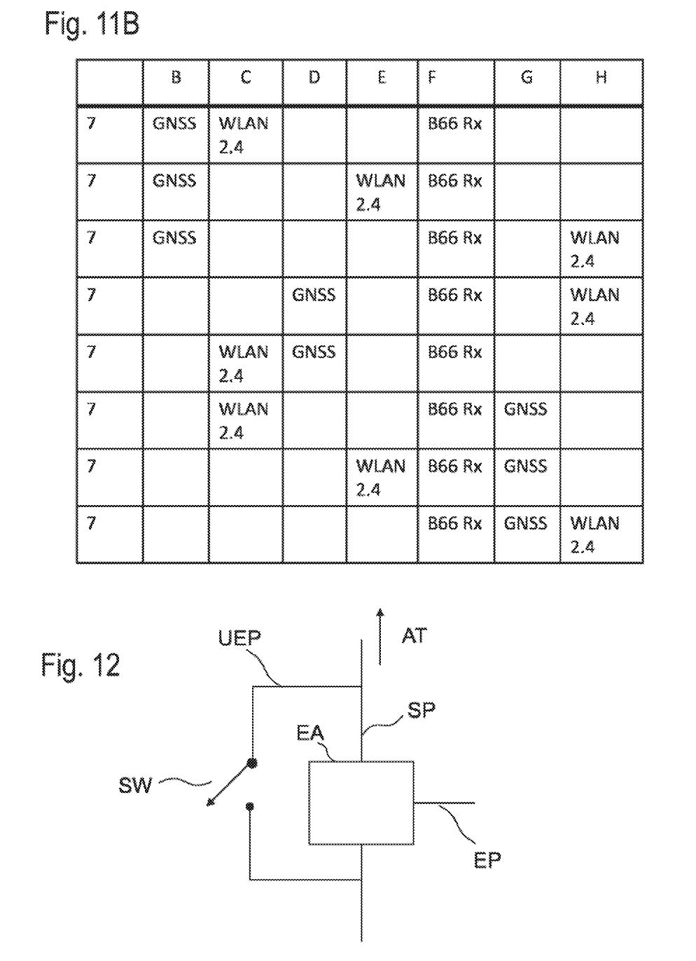

FIG. 11A specifies how three extractor arrangements which can be used in the front-end module according to the invention can be distributed over the various extractor-arrangement positions according to FIG. 4,

FIG. 11B shows further positioning possibilities for a combination of three extractor arrangements in a front-end module,

FIG. 11C shows the exemplary embodiment of a novel hexaplexer [ . . . ] the passband characteristics between the antenna connection and the various sub-paths,

FIG. 12 shows an extractor arrangement with a switchable bypass path,

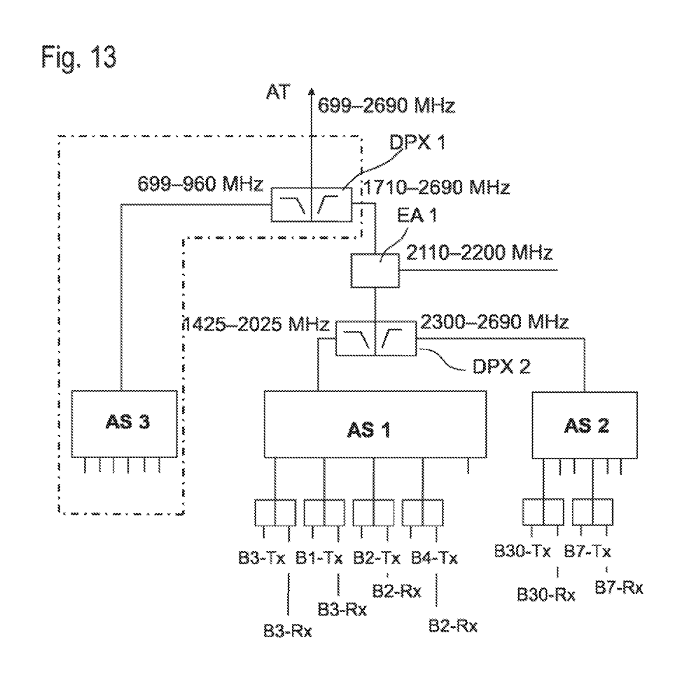

FIG. 13 shows an exemplary embodiment with novel duplexer combinations,

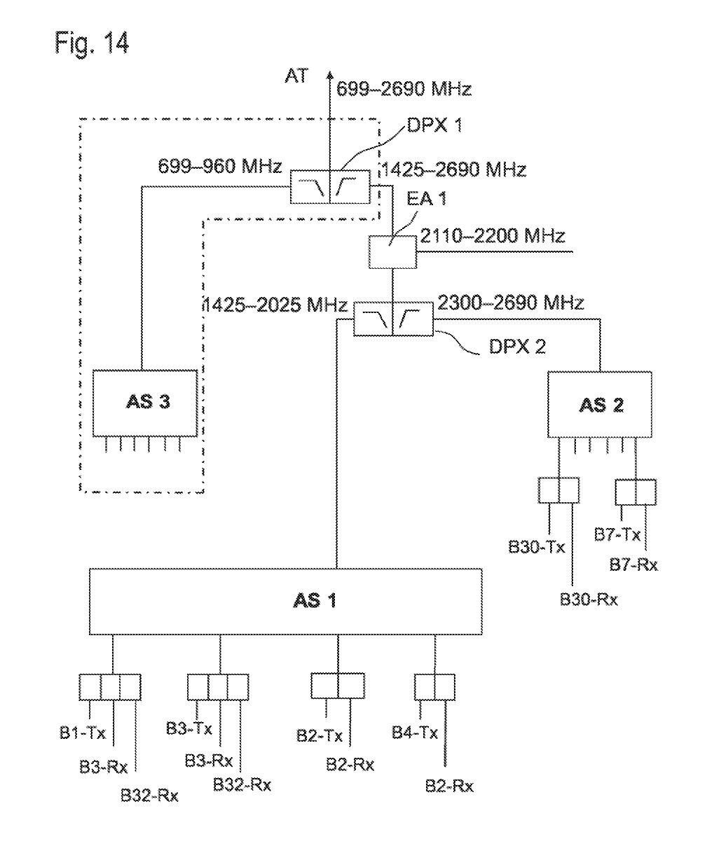

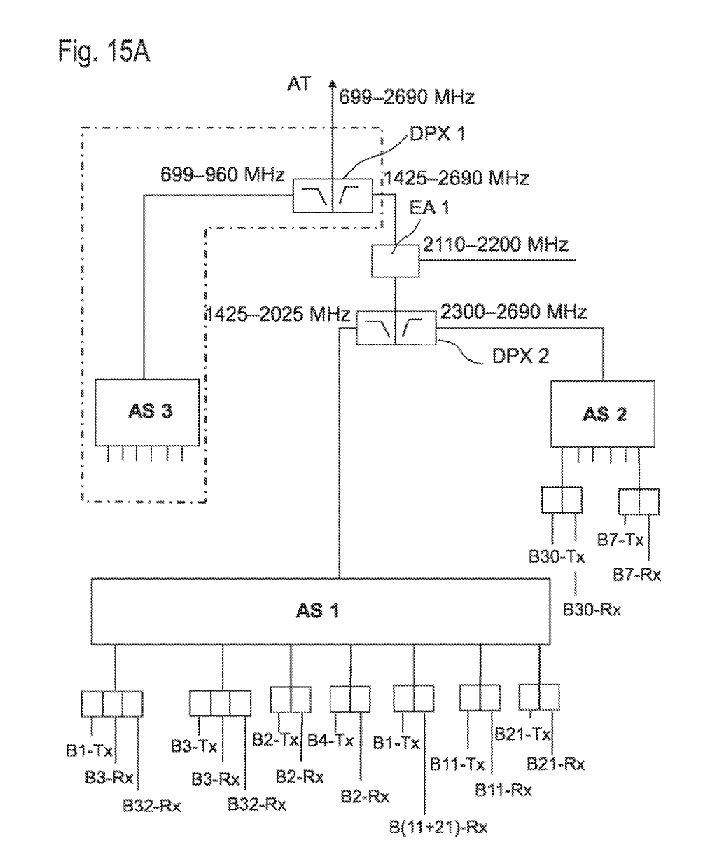

FIG. 14 shows an exemplary embodiment with a mixed duplexer and two mixed triplexers,

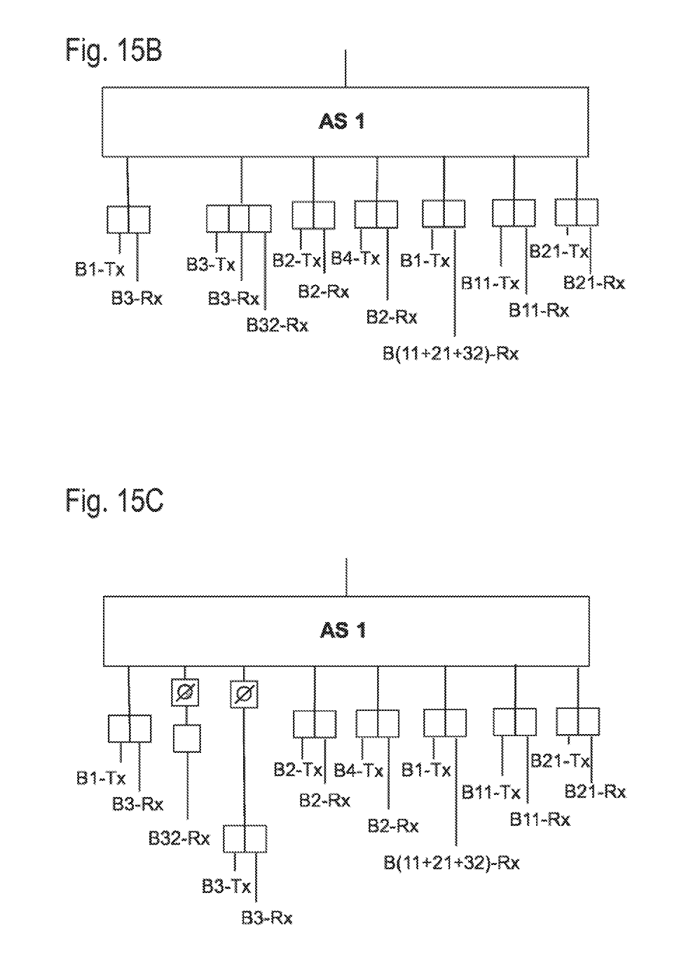

FIG. 15A shows a further exemplary embodiment with mixed duplexers and triplexers,

FIG. 15B shows a further exemplary embodiment which differs from FIG. 15A in the first antenna switch,

FIG. 15C shows a further exemplary embodiment which also differs from FIG. 15A only in the first antenna switch,

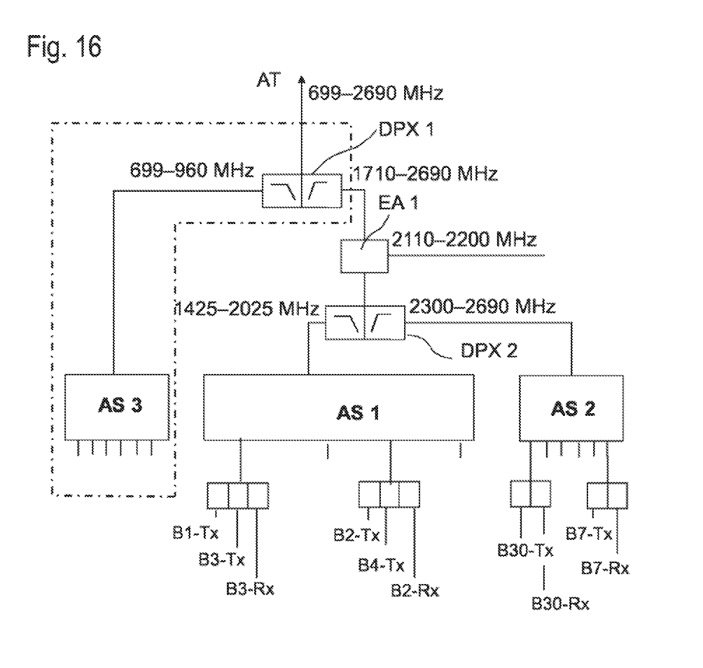

FIG. 16 shows a further exemplary embodiment with two mixed triplexers,

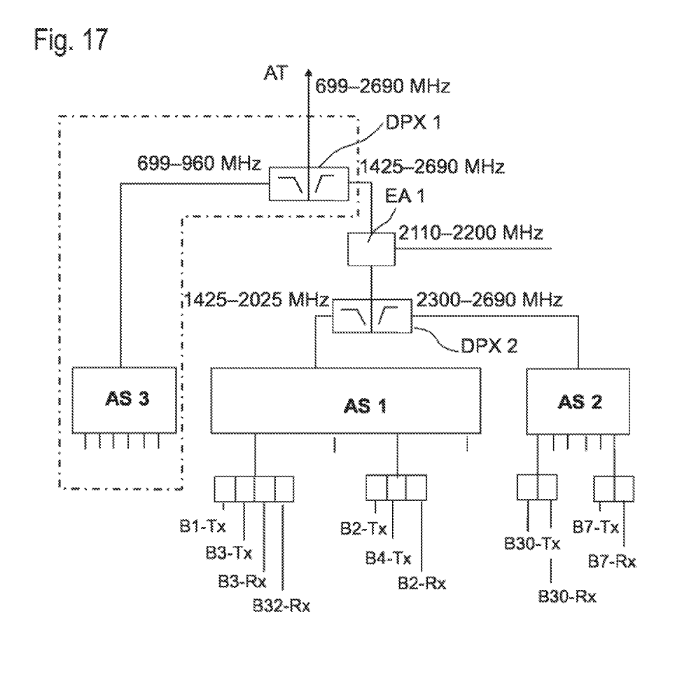

FIG. 17 shows a further exemplary embodiment with a mixed triplexer and a mixed quadplexer,

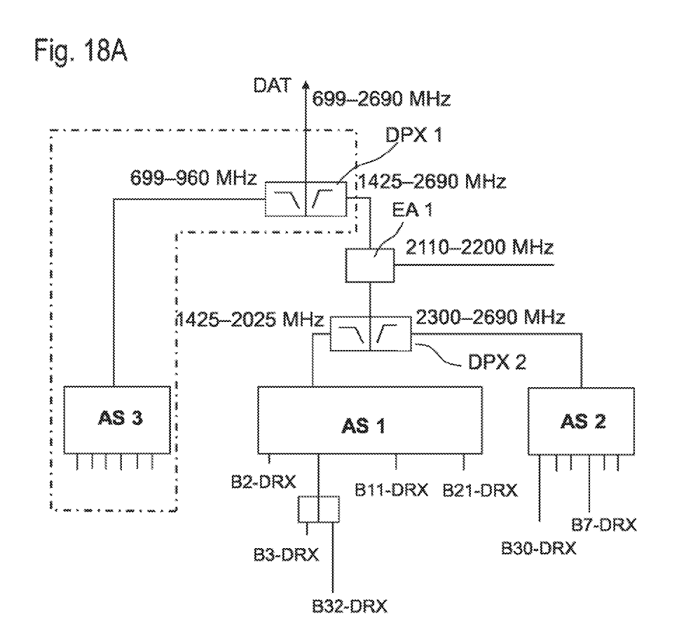

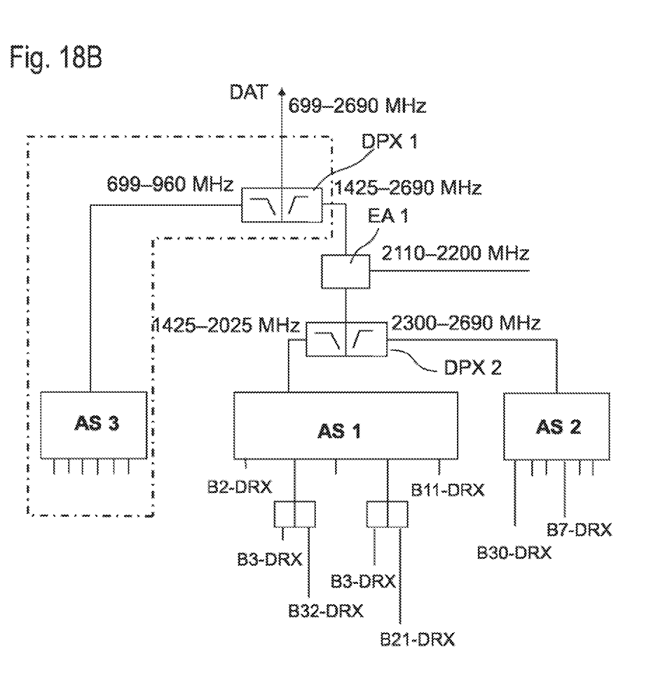

FIG. 18A shows an inventive exemplary embodiment for a front-end module connectable to a diversity antenna and having a mixed diversity diplexer,

FIG. 18B shows an inventive exemplary embodiment for a front-end module connectable to a diversity antenna and having two mixed diversity diplexers,

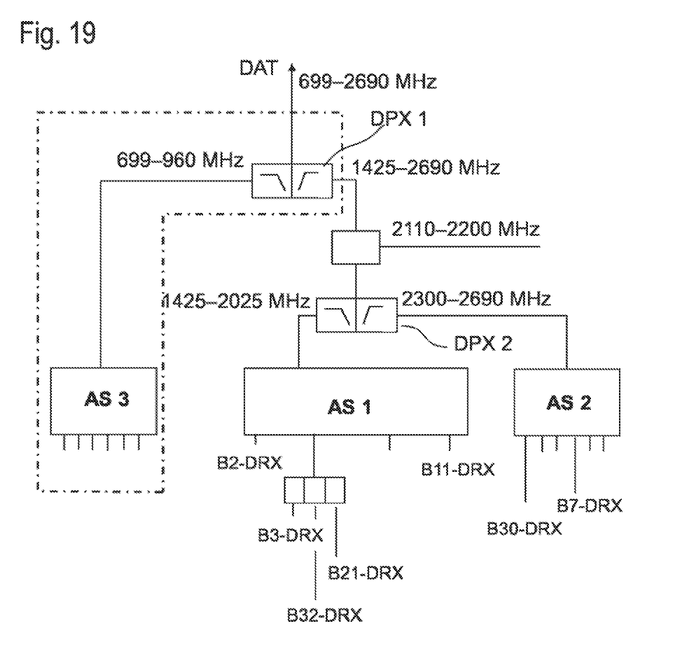

FIG. 19 shows a further front-end module according to the invention which is connectable to a diversity antenna and has a mixed diversity triplexer at an antenna switch,

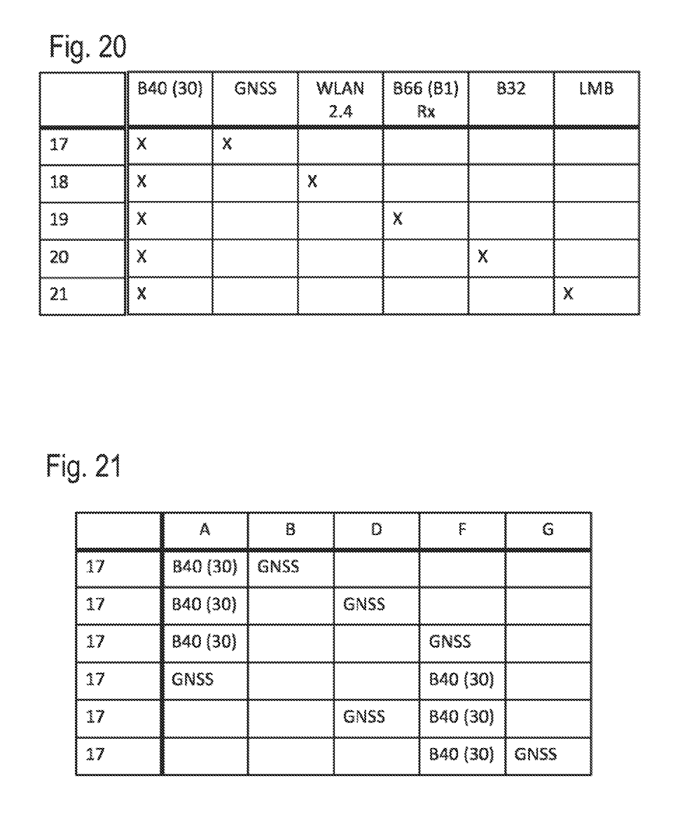

FIG. 20 shows possible combinations that can be realized with two extractor arrangements in a front-end module according to the invention, wherein at least one extractor arrangement is designed for band 30 (Tx and Rx) and/or band 40,

FIG. 21 shows a possible combination of two extractor arrangements and their arrangement in a front-end module according to the invention,

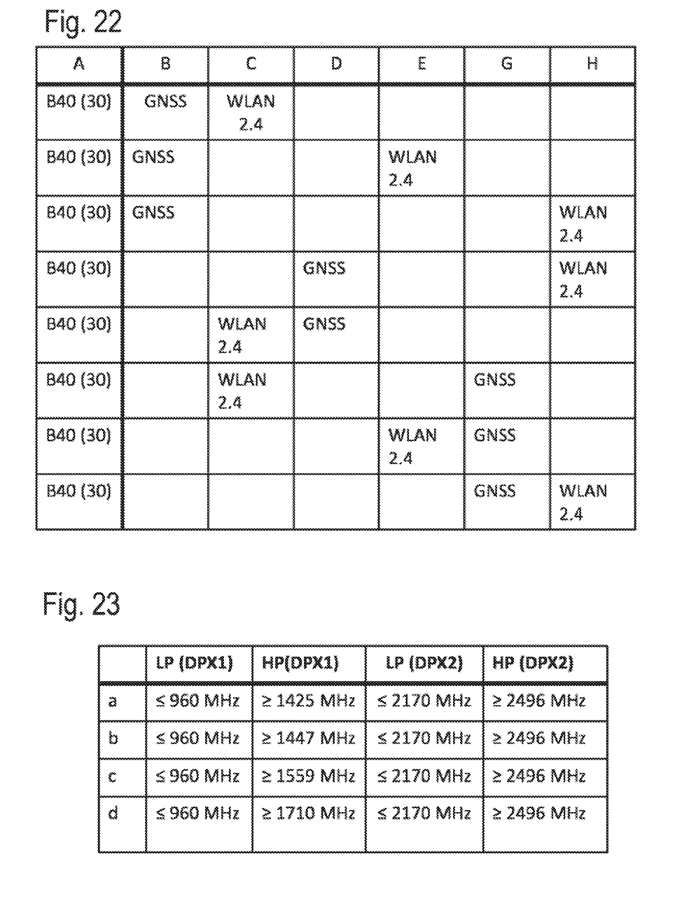

FIG. 22 shows various possibilities of arranging three extractor arrangements in a front-end module according to the invention,

FIG. 23 shows different possibilities of setting the frequencies of the passbands for two diplexers which can be used in a front-end module according to the invention,

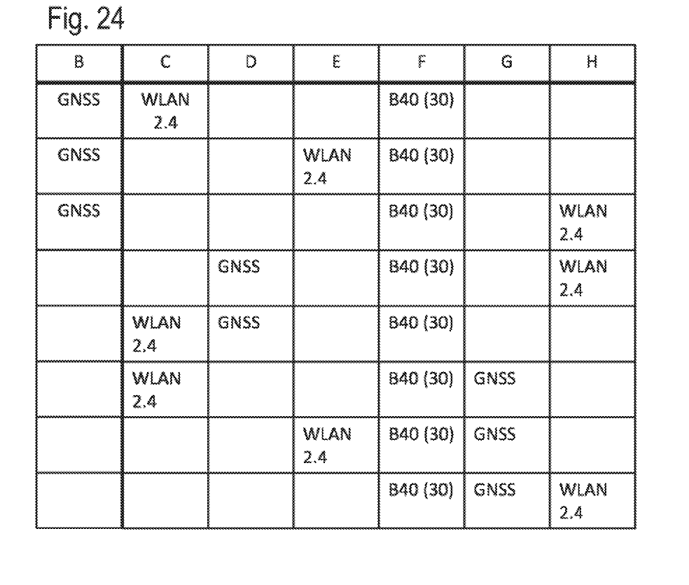

FIG. 24 shows how three different extractor arrangements can be positioned in a front-end module,

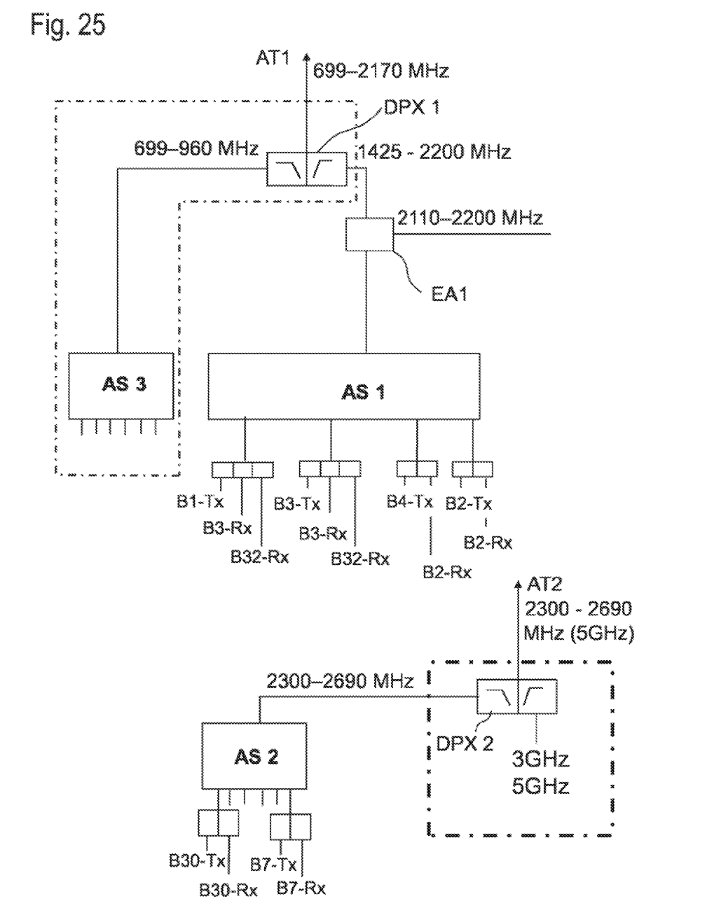

FIG. 25 shows a front-end module according to the invention which has two mixed triplexers and one mixed duplexer on an antenna switch in combination with a second antenna,

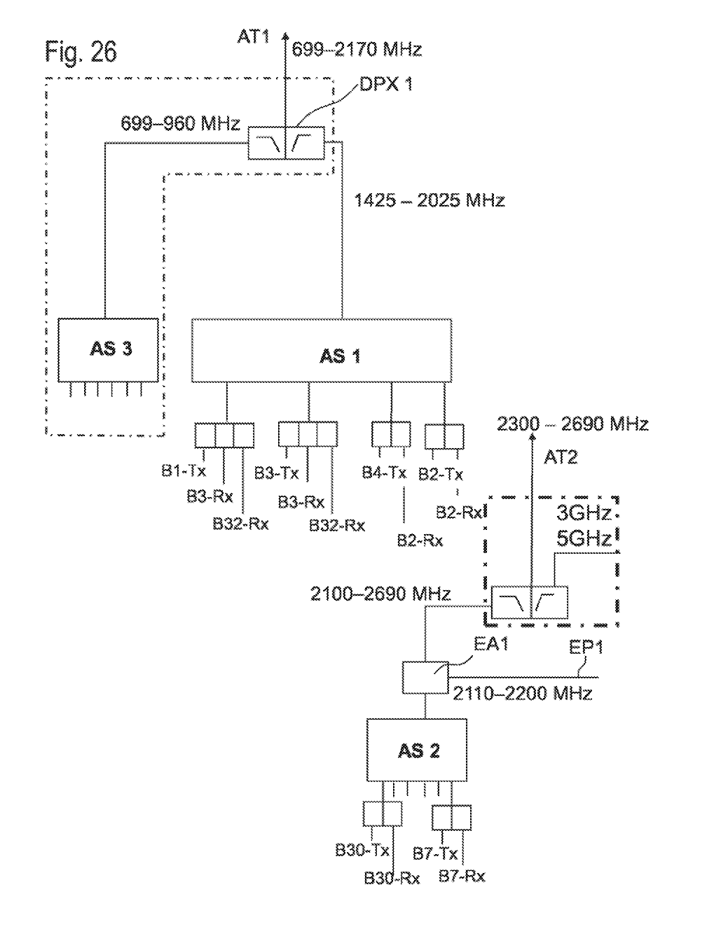

FIG. 26 shows a further variation of a front-end module with two antennas and mixed triplexers on an antenna switch,

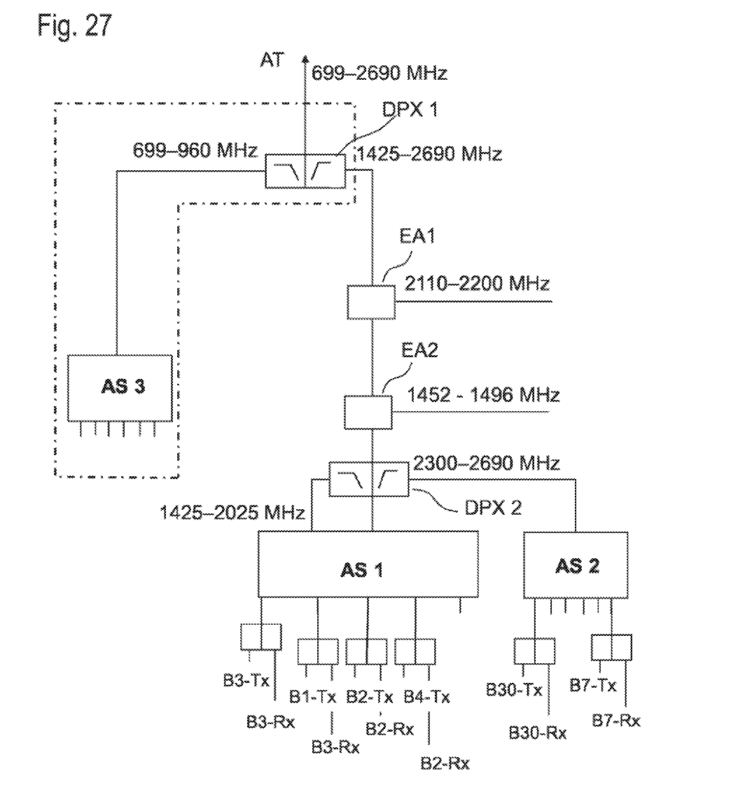

FIG. 27 shows a front-end module with two extractor arrangements and two mixed duplexers on an antenna switch,

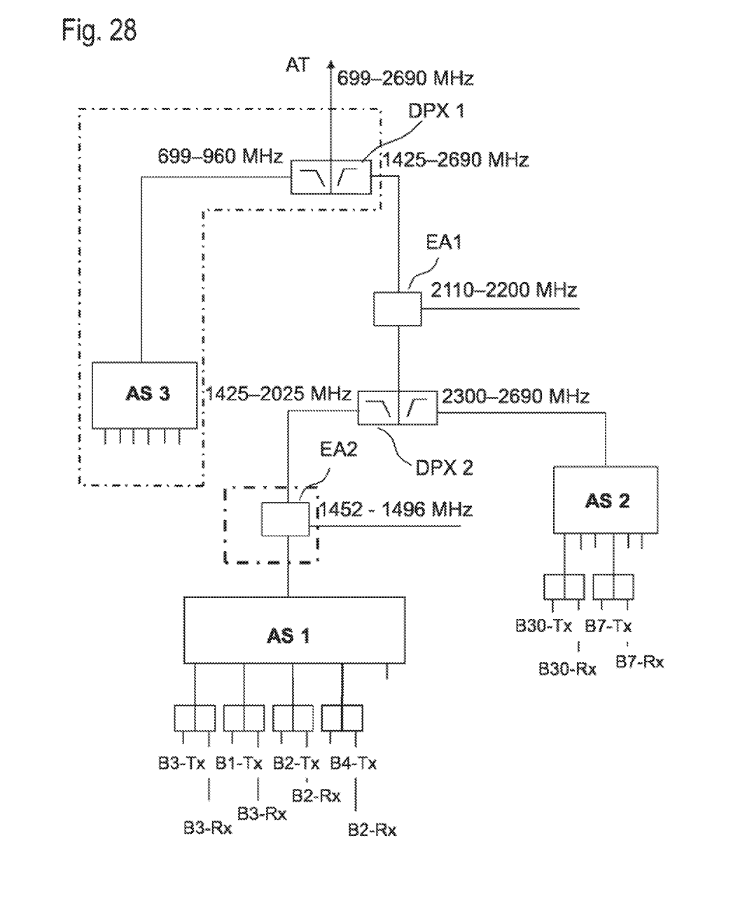

FIG. 28 shows a further front-end module with two extractor arrangements, which are differently positioned from the embodiment shown in FIG. 27, as well as two mixed duplexers on an antenna switch.

FIG. 1A shows a simple front-end module according to the invention which, by means of two diplexers DPX1, DPX2, can separate three sub-paths TP1 to TP3 from each other, which are in each case assigned to one frequency sub-range. A further frequency band, which is arranged between two of the frequency sub-ranges, is extracted from the signal path SP by means of an extractor arrangement EA1.

A first diplexer DPX1 is connected to an antenna connection AT via a signal path SP. The antenna connection AT can be connected to an antenna and is capable of transmitting an RF signal between 699 MHz and 2690 MHz. The first diplexer DPX1 includes a low-pass filter and a high-pass filter, which in each case assign a frequency sub-range to a sub-path TP at the output of the diplexer DPX. At the output of the low-pass filter, the first sub-path TP1 starts, which, for example, is designed for a low-band range with frequencies between 699 MHz and 960 MHz. At the output of the high-pass filter, on the other hand, frequencies of 1425 MHz to 2690 MHz or 1710 MHz to 2690 MHz are transmitted.

A first extractor arrangement EA1, which can be connected to the first diplexer DPX1, is arranged in the signal path SP. The extractor arrangement EA1 can be arranged between the antenna connection AT and the first diplexer or in the signal path at the output of the first diplexer.

The first extractor arrangement is designed for an extractor band which is passable for the RX bands of band 1, band 4, and/or band 65/66. These frequencies are extracted from the signal path via an extraction path EP1. The notch filter contained in the extractor arrangement EA1 has a stopband, so that frequencies within the stopband cannot pass through the signal path, but are routed out in a separate path via the extraction path EP1 and the bandpass filter arranged therein, viz., in the said extraction path EP1 or extracted from the signal path SP.

After the extraction arrangement EA1, a second duplexer DPX2 is arranged in the signal path by means of which the remaining frequency range is further divided into a mid-band, which covers a frequency range between 1425 MHz and 2025 MHz or, alternatively, between 1710 MHz and 2025 MHz, and a high-band range, which covers frequencies of 2300 MHz to 2690 MHz. At the output of the diplexer, signals with frequencies in the mid-band and high-band are assigned, accordingly, to a second sub-path TP2 or to a third sub-path TP3.

By a range between 2110 MHz and 2200 MHz being filtered out of the signal path via the extraction path EP1, the second diplexer DPX2 can be designed with a greater diplexer separation, which is possible with technically simpler measures. It thus suffices to position the diplexer spacing between the upper limit of the lowpass filter at 2025 MHz and the beginning of the high-band, corresponding to the lower limit of the passband at 2300 MHz, which corresponds to a diplexer spacing of 275 MHz. Without the extractor arrangement EA1, a diplexer would be needed to separate mid-band and high-band, whose diplexer spacing should be set between 2200 MHz to 2300 MHz, and hence to a value of only 100 MHz. With the extractor arrangement, the technical design of the diplexer is greatly facilitated, and a built-in diplexer in LTCC or laminate is even feasible. Of course, the diplexer can also, as a discrete filter, be made up of SMD inductors and SMD capacitors.

Provided that the second frequency range, which, at the output of the low-pass filter of the second duplexer DPX2, is assigned to the second sub-path TP2, does not have to include band 34 frequencies, the upper limit of the low-pass filter can be lowered further to value of 1995 MHz, thereby increasing the diplexer spacing to a possible 305 MHz.

Thus, with the illustrated front-end module, three frequency ranges and one extraction band can be separated cleanly, and operated independently of one another in parallel. This can be achieved with diplexers which have an easily realizable, wide diplexer spacing of at least 275 MHz to 305 MHz for the second diplexer, as well as of 465 MHz to 750 MHz for the first diplexer DPX1.

FIG. 1B shows four passband curves, which are defined between the antenna connection AT and the output for the first sub-path TP1 at the low-pass output of the first diplexer DPX1, between the antenna connection AT and the output for the first sub-path TP1 at the low-pass output of the second diplexer DPX2, as well as between the antenna connection AT and the output of the high-pass of the second diplexer DPX2.

It is shown that, in the first sub-path TP1, low-band frequencies are obtained with little insertion loss, wherein the restricted range with high attenuation is cleanly isolated. Signals in the mid-band range, between 1710 MHz and 1990 MHz in this case, are transmitted in the second sub-path TP2. Because the extractor structure EA prevents the passing of frequencies in the restricted range of the notch filter of the extractor structure, and the restricted range is arranged on the upper edge of the low-pass filter, the right flank of the passband curve for the mid-band drops off sharply, which is advantageous for good isolation of the frequency sub-domains.

The frequencies extracted at the extractor path EP1 have passed the bandpass filter of the extractor structure and likewise have a passband with sharply-dropping flanks.

The left flank of the high-band allocated to the third sub-path TP3 has a sharp rise as well and is thus cleanly isolated compared to the mid-band allocated to the second sub-path TP2.

FIG. 2A shows a further front-end module, which is formed essentially by the front-end module shown in FIG. 1A. The first diplexer, which can be connected to the antenna connection AT, is configured to the same frequency domains as that in FIG. 1A. A first extractor structure EA1 is connected to the output of the high-pass of the first diplexer; the extractor structure is configured in this embodiment for the extraction of frequencies in a range of band 30 and/or band 40. Thus, frequencies between 2300 MHz and 2400 MHz can be extracted in the first extraction path EP1. The restricted range of the extractor structure EA1 is, accordingly, configured such that it comprises at least the frequencies of the extraction path EP1.

A second duplexer DPX2, the passband ranges of which are positioned on both sides of the restricted range of the first extractor structure EA1, is provided behind the first extractor structure EA1. A frequency domain between 1425 MHz and 2200 MHz is, accordingly, transmitted at the output of the low-pass of the second duplexer DPX2, while frequencies of 2496 MHz to 2690 MHz are allocated to the third sub-path TP3 at the output of the high-pass.

The distance between the mid-band of the second sub-path TP2 and the high-band, which is allocated to the third sub-path TP3, is increased here as well to a value of 296 MHz, because the frequencies at the lower limit of the high-band range no longer have to be allocated to the third sub-path TP3 via the second diplexer DPX2. Thus, the diplexer spacing of 100 MHz is increased to 296 MHz with the assistance of the first extractor structure. This also enables integration of the diplexer with an LTCC substrate or a laminate, using simple technology. Of course, it is also possible to implement the diplexer from SMD inductivities and SMD capacitors.

FIG. 2B shows passband curves, which, in the configuration according to 2A, are measured between the antenna connection AT and the respective sub-path TP1, TP2, and TP3, and/or signals that can reach from the antenna connection AT to the first extraction path EP1. It is also shown here that the low-band located far away, as compared to the other frequencies sub-domains, is isolated according to the first sub-path TP1 with high attenuation, as compared to the frequency sub-domains located higher. The curve for the mid-band range, which is allocated to the second sub-path TP2 at the output of the low-pass of the second diplexer, drops off sharply at the right flank.

The left flank of the high-band range, which is allocated to the third sub-path TP3, rises sharply. The frequencies that can reach the first extraction path EP1 are located precisely between the high-band and low-band ranges, which correspond to the frequency sub-domain of the second diplexer, and thus are cleanly isolated from the other bands and/or frequency domains. The passband curves drop off sharply at the critical boundaries between the frequencies of the third sub-path and the extraction path, as well as between the frequencies of the second sub-path and the extraction path. This thus results in a clean isolation of the three frequency sub-domains here also, which in turn are isolated cleanly from frequencies of the first extraction path EP1.

FIG. 3 shows a schematic representation of a possible configuration of an extractor structure used according to the invention. Such an extractor structure is essentially known from European patent application EP 1,683,275A. The extractor structure EA can be integrated into any signal path SP, and then an extraction path EP branches off from this. In doing so, a notch filter NF arranged in the signal path SP is used to reflect frequencies of the restricted range with a high level of effectiveness, so that they cannot pass the notch filter NF. Signals with frequencies in the restricted range are instead routed to an extraction path EP, which is connected to a node between the antenna connection and the notch filter NF.

A bandpass filter BP arranged in the extraction path EP is used for further filtering of the frequencies in the restricted range, so that a narrow frequency band with clean flanks can be extracted in the further extraction path EP. Preferably, weak RX signals can be extracted from the signal path with the extractor structure.

However, the invention additionally utilizes the extractor structure to enlarge the distance between the isolating frequency domains adjacent in the sub-paths, and thus to facilitate the implementation of the diplexer required to isolate the frequency domains.

Using a more schematic representation, FIG. 4 shows a front-end module with a first diplexer DPX1 and a second diplexer DPX2 connected in series. Thus, the three sub-paths TP1, TP2, and TP3 can be isolated from one another in the front-end module. The sub-paths are numbered individually for each exemplary embodiment and may deviate from this in a different exemplary embodiment. Accordingly, the frequency domains, which are allocated to a certain sub-path or a sub-path with a certain numbering, may differ.

Different positions can then be provided for extractor structures between the antenna connection AT and the various sub-paths TP1 to TP3. Thus, up to three extractor structures, for example, can be provided at positions F, G, and H between the antenna connection and the first duplexer. Independently of this, up to three extractor structures can be provided at positions A. B, and C between the first duplexer DPX1 and the second duplexer DPX2. The different extractor structures are used to extract different extractor bands. Preferably, the first of the three extractor structures comprises band 30 and/or B40.

Further extractor structures can be connected to the output of the second diplexer DPX2, e.g., to position D at the output of the low-pass of the second diplexer and/or to position E at the output of the high-pass of the second diplexer DPX2. Due to the different options for positioning one or more extractor structures, the passband ranges of the diplexer can be differently combined and different bands filtered out or isolated as needed.

The sub-structure outlined with a dotted line is optional. This means that a front-end module without the first diplexer DPX1 and the possible upstream extractor structures is also considered to be in accordance with the invention.

FIG. 5A shows a part of a structure which is part of a front-end module according to the invention. In this case, a first extractor structure EA1 is arranged between an antenna connection AT and a first duplexer DPX1. This does not rule out further elements being arranged between the antenna connection and first extractor structure, or between a first duplexer and the transmit/receive part of the front-end module and/or the communication device.

In this exemplary embodiment, signals between 1425 MHz and 2690 MHz or between 1710 MHz and 2690 MHz are transmitted via the antenna connection AT, depending upon whether frequencies of 1559 MHz to 1605 MHz are to be transmitted and/or filtered out for Galileo, BeiDou, Glonass and/or GPS (GNSS), or bands 11, 21, and 32.

A filter for band 32 Rx automatically comprises band 11 Rx, whereas the narrowband 21 Rx connects directly above to band 11 so that correspondingly broader filters can also comprise band 21 Rx, which thus always represents an option. The first extractor structure EA1 allocates an extraction band between 2110 MHz and 2200 MHz to the extraction path. The bandpass filter is correspondingly configured for this frequency domain in the first extraction path EP1, and has a corresponding passband.

The restricted range of the first extractor structure EA1 enables configuration of the first diplexer DPX1 such that the right flank of the low-pass ends at 2025 MHz. The high-pass accordingly starts to transmit at 2300 MHz and can allocate a frequency domain of up to 2690 MHz to the second sub-path TP2. The extractor band allocated to the first extraction path EP1 comprises RX bands of band 1, band 4, and band 65/66, which are all between 2110 MHz and 2200 MHz.

FIG. 5B shows the transmission curves for signals that can be transmitted between the antenna connection AT in the first sub-path TP1, between the antenna connection AT and the second sub-path TP2, and/or between the antenna connection AT and extraction path EP1, in a configuration according to FIG. 5A. The good isolation between the first sub-path TP1 for low-band and mid-band is shown again here as compared to the high-band transmitted in the second sub-path TP2. The extractor band, which can be extracted in the first extraction path EP1, is completely isolated from this. The transmission curve for the extractor band has a bandpass characteristic, due to the bandpass filter of the extractor structure.

FIG. 6 shows a table of the frequency domains and/or bands that can be extracted in a simple manner from the signal path by means of extractor structures. Pairs of bands are shown, which can be extracted together in a front-end module with the extractor structures. One of the extractor structures in this case covers the frequency domain of 2110 MHz to 2200 MHz. This includes the RX bands of bands 1, 4, and 66. The second extractor structure can cover a frequency domain for Glonass (GNSS), WLAN 2.4, frequencies of band 30 and/or band 40, RX frequencies of band 32, or the lower mid-band LMB, which comprises frequencies of 1425 MHz to 1511 MHz.

FIG. 7 shows a table that indicates how two exemplary extractor structures—for RX frequencies of band 1/4/65/66 and for frequencies of 1559 MHz to 1605 MHz (GNSS) in this case—can be distributed to the various possible positions in the front-end module of FIG. 4. It shows that the extractor structure can be arranged at positions F and G between the antenna connection and the first duplexer, as well as at positions A and B between a first diplexer and second diplexer, as well as at position D at the output of the low-pass of the second duplexer DPX2.

FIG. 8 provides four possible configurations for the passband ranges of the first and second diplexers, DPX1 and DPX2, as they can be used for selected extractor combinations according to FIGS. 6 and 7 in a front-end module schematically shown in FIG. 4. The low-band ends at the low-pass LP of the first duplexer at 960 MHz for all four variants, a, b, c, and d. The signal pending at the high-pass output of the first duplexer starts at 1425 MHz for case a, at 1450 MHz for case b, at 1559 MHz for case c, and at 1710 MHz for case d. The low-pass LP of the second duplexer ends at an upper limit of 1995 MHz or at 2025 MHz in all cases, a through d. Signals with frequencies ≥2300 MHz can pass the high-pass HP of the second duplexer DPX2 in all 4 diplexer configurations, a through d.

FIG. 9 shows possible combinations as to how three different extractor structures for three different bands can be positioned at different positions in a front-end module according to the invention. One of the extractor structures is used to extract the Rx frequencies of band 66. Two further bands, which are selected, independently of one another, from GNSS, WFAN 2.4, band 30/band 40, band 32, and LMB, are extracted with further extractor structures. There are ten different possibilities for the selection of two additional bands.

FIG. 10A shows a part of a structure which is part of a front-end module according to the invention. In this case, similar to FIG. 5A, a first extractor structure EA1 is arranged between an antenna connection AT and a first duplexer DPX1. This does not rule out further elements being arranged between the antenna connection and first extractor structure, or between a first duplexer and the transmit/receive part of the front-end module and/or the communication device.

In this exemplary embodiment, signals between 1425 MHz and 2690 MHz or between 1425 MHz (1710 MHz) and 2690 MHz are transmitted via the antenna connection AT, depending upon whether frequencies are to be transmitted and/or filtered out for Galileo, BeiDou, Glonass and/or GPS (GNSS), or at least one of bands 11, 21, and 32. The first extractor structure EA1 allocates an extraction band between 2300 MHz and 2400 MHz to the extraction path. The bandpass filter is correspondingly configured for this frequency domain in the first extraction path EP1 and has a corresponding passband.

The restricted range of the first extractor structure EA1 enables configuration of the first diplexer DPX1 such that the right flank of the low-pass ends at 2200 MHz. The high-pass accordingly starts to transmit at 2496 MHz and can allocate a frequency domain of up to 2690 MHz to the second sub-path TP2. The extractor band allocated to the first extraction path EP1 comprises the frequencies of band 30 and/or band 40, both of which are between 2300 MHz and 2400 MHz.

FIG. 10B shows the transmission curves for signals that can be transmitted between the antenna connection AT in the first sub-path TP1, between the antenna connection AT and the second sub-path TP2, and/or between the antenna connection AT and extraction path EP1, in a configuration according to FIG. 5A. The good isolation between the first sub-path TP1 for low-band and mid-band is shown again here as compared to the high-band transmitted in the second sub-path TP2. The extractor band, which can be extracted in the first extraction path EP1, is completely isolated from this. The transmission curve for the extractor band has a bandpass characteristic, due to the bandpass filter of the extractor structure.

A table in FIG. 11A shows eight different options for arranging the three extractor structures for exemplary three-band combination no. 7 according to FIG. 9 in a front-end module, as is schematically shown in FIG. 4. What all eight different structures have in common is that the always present extractor structure for Rx band 65/66 remains in position A, which is between the first and the second duplexers.

The duplexers are also configured for this distribution of the extractor structures via the front-end module, as indicated in FIG. 8.

A table in FIG. 11B shows eight further structure options for combining three extractor structures according to combination no. 7. What all these eight variants have in common is that the extractor structure for band 66 Rx is allocated to position F, i.e., between the antenna connection AT and the first duplexer DPX1.

The duplexers are also configured for these positions of the extractor structures, as indicated in FIG. 8.

Using simulated passband curves, FIG. 11C shows how a hexaplexer can be obtained, which isolates six different frequency domains cleanly from one another in a front-end module with the assistance of three extractor structures for GNSS, band 1 Rx, and WFAN 2.4, which can be arranged, for example, between two diplexers:
1. a low-band between 699 and 960 MHz
2. GNSS at 1575 MHz
3. the Rx band of band 66 (band 1)
4. a mid-band range MB between 1710 MHz (or 1425 MHz) and 1990 MHz
5. WLAN 2.4 MHz
6. a high-band range HB between 2300 MHz and 2380 MHz and/or between 2510 MHz and 2690 MHz

The demand at the diplexer, the mid-band MB, and high-band HB is simplified—-isolated from one another, in this case, in that the diplexer spacing can be enlarged and adjusted to between 1995 MHz (or 2025 MHz) and 2300 MHz.

FIG. 12 shows an option for equipping a front-end module with any number of extractor structures without having to deal with unnecessary losses if one or more extractor structures is not required for an operating mode. To this end, a bypass path UEP is provided, which short-circuits a node in the signal line upstream of the extractor structure with a node downstream of the extractor structure, and thus bypasses the notch filter. A switch SW, which can activate or deactivate the bypass path, is arranged in the bypass path UEP. When the switch SW is closed, the extractor structure is inactive, while it is active when the switch SW is open, and extracts the corresponding extractor band via the extraction path EP. Thus, in all exemplary embodiments, the extractor structures can be optionally bypassed with such a bypass path UEP, even if this is not shown in the corresponding figures.

In this manner, it is possible to precisely switch the extractor structure to active, which is required for the respective operating mode—particularly for the special carrier aggregation mode.

By means of a schematic block diagram, FIG. 13 shows a front-end module according to a further exemplary embodiment of the invention. In this module, antenna connection AT is connected to a first duplexer DPX1. The antenna is designed for frequencies of 699 MHz to 2690 MHz, at a minimum. The first duplexer comprises a high-pass/low-pass combination, wherein the low-pass isolates a frequency domain of 699 MHz to 960 MHz. The high-pass isolates frequencies of 1710 MHz to 2690 MHz and allocates them to a second sub-path. In said second sub-path, a first extractor structure EA1 is inserted, which is configured for extracting band 65/66 Rx or frequencies between 2110 and 2200 MHz. The extractor structure EA1 can be equipped with a bypass path, as in FIG. 12 (not shown).

A second duplexer DPX2, which in turn comprises a high-pass/low-pass combination for isolating two frequency sub-domains, follows this in the second sub-path downstream of the extractor structure EA1. The low-pass in this case isolates signals of from 1425 MHz to 2025 MHz and allocates them to a first antenna switch. At the output of the high-pass, frequencies of 2300 MHz to 2690 MHz are diverted and routed to a second antenna switch AS2.

The output of the low-pass at the first duplexer DPX1 is connected to a third antenna switch AS3, which isolates the signals into the various bands of the low-band range.

The overall arrangement can be considered a quadplexer, which can isolate signals from four different band ranges, independently of one another, viz., the low-band range, the mid-band range, and the high-band range, wherein a fourth range is isolated as an individual band via the extractor structure.

In one variant of this front-end module, the first diplexer DPX1 can be dispensed with, such that the antenna connection AT is connected directly to the first extractor structure EA1. The remaining units then represent a triplexer for mid-band, high-band, and band 66. This corresponds to the arrangement shown in FIG. 13, without the optional elements within the closed dotted line.

Antenna switches AS1, AS2, and AS3 are used to connect the respective signal path or sub-path with at least one band channel in each case, which can be used bidirectionally for transmit and receive signals. A filter device is provided in each band channel.

In the present exemplary embodiment, four duplexers are provided that are arranged one in each band channel. A first duplexer is used for isolating the RX/TX from band 2. A further duplexer is used for isolating the RX/TX from band 3. Furthermore, two novel, mixed duplexers are provided, in which TX and RX filters belong to different bands. A first mixed duplexer combines, for example, a TX filter for band 1 with an RX filter for band 3. A second mixed duplexer combines an RX filter of band 2 with a TX filter of band 4. Thus, it is possible, for example, to filter out RX signals of band 2 via the pure band 2 duplexer or via the mixed duplexer. The same thing applies to RX signals of band 3, which can be filtered out via the first mixed duplexer or the pure band 3 duplexer. The duplexing in band 4 is not carried out by a duplexer. TX signals for band 4 are routed in the second mixed duplexer to the first antenna switch AS1; the RX signals of band 4, on the other hand, are diverted via the first extraction path, which of course also covers the frequencies of band 4 RX. The duplexing for band 1 functions similarly.

Further band channels are connected and, optionally, can be switched on, e.g., duplexers for band 7 and band 30, at the second antenna switch AS2 for the high-band range.

Of course, it is also possible to connect further band channels and the corresponding filter elements to the respective antenna switches for low-band (antenna switch AS3), for mid-band (antenna switch AS1), and for high-band (antenna switch AS2).

With the front-end module shown in FIG. 13, a downlink carrier aggregation mode is possible for RX signals of band 1 and band 3, although both are established in the same band range (mid-band). Because the low-band anti-band ranges are diverted via different paths, carrier aggregation modes, in which a low-band and a high-band are combined with band 1 and band 3, are also possible. Such a quad-carrier aggregation can work, for example, in parallel in bands B20, B1, B3, and B7.

Because a filter configured for band 25 or a duplexer configured for band 25 simultaneously also covers the frequencies of band 2, just as an RX filter for band 66 also covers the RX frequencies of band 4 and band 1, it is possible with the given structures to implement duplexers, which combine the other RX and TX filters of different bands, e.g., band 4 TX with band 2 RX, band 4 TX with band 25 RX, band 66 TX with band 2 RX, or band 66 TX with band 25 RX. Together with the pure band 2 or band 25 duplexers, RX carrier aggregation operating processes are possible in which band 2 and band 4, band 2 and band 66, band 25 and band 4, or band 25 and band 66 are operated simultaneously or in parallel.

Because the low-band and high-band ranges are isolated, obviously, four bands can also be operated in parallel, e.g., one band in the low-band, band 25, band 66, and one band in the high-band range. In a special embodiment, a downlink carrier aggregation mode is supported for band 5, band 25, band 66, and band 30.

FIG. 14 shows a further exemplary embodiment of a front-end module, which corresponds to the exemplary embodiment shown in FIG. 13 with respect to the diplexer, the extractor structure, and the provision of three antenna switches AS1, AS2, and AS3. Only the band channels connected to the first antenna switch AS1 are different.

It is proposed for this exemplary embodiment to connect mixed micro-acoustic triplexers to antenna switch AS2 in order to enable triplexing in the respective band channel. A first triplexer, for example, comprises filters for band 1 TX/band 3 RX/band 32 RX. A further micro-acoustic triplexer comprises filters for band 1 TX/band 3 RX/band 32 RX. A carrier aggregation operating process for three receiving bands, which can be operated in parallel in band 1, band 3, and band 32, is possible with these two triplexers and an extractor structure for band 66 (or band 1 or band 4).

Because low-band and high-band ranges are isolated with the module shown, downlink carrier aggregation operating modes are possible in at least five RX bands. For example, one band in the low-band range, band 1, band 3, band 32, and one band from the high-band range can be combined here and operated in parallel in RX. A carrier aggregation mode, for example, is possible in band 20, band 1, band 3, band 32, and band 7.

Even the exemplary embodiment according to FIG. 15A does not differ from the embodiments according to FIGS. 13 and 14, with the exception of the band channels connected to the first antenna switch AS1 and/or the filter elements contained therein. In addition to the band channels shown in FIG. 14, three novel micro-acoustic mixed duplexers are provided for Japanese bands and/or for bands used in Japan.

A first mixed duplexer operates band 1 TX and the combination of band 11 plus band 21 RX. The last-mentioned RX filter comprises the narrow frequency domains, which are adjacent to one another and not overlapping, for band 11 RX and band 21 RX. A second novel, mixed duplexer comprises band 1 TX and band 11 RX. A third novel, mixed duplexer comprises band 1 TX and band 21 RX. Each one of the three mentioned mixed duplexers can enable a carrier aggregation mode for band 1 and band 11 or for band 1 and band 21 with regard to RX in conjunction with a pure band 11 or band 21 duplexer and the extractor structure for band 66.

Because the low-band range and the high-band range are isolated from the first antenna switch AS1 through isolated signal paths, obviously, carrier aggregation processes are also possible in which one band of the low-band range plus band 1 plus band 11 (band 21) and one high-band from the high-band range are combined. For example, a downlink carrier aggregation mode is thus supported, in that a mode is possible in band 18, band 1, band 11 (and/or band 21), and band 7. Of course, other bands of the high-band and low-band range can be combined as an alternative to this, e.g., band 30 for the high-band range.

Even the exemplary embodiment according to FIG. 15B does not differ from the embodiments according to FIGS. 13, 14, and 15A, with the exception of the band channels connected to the first antenna switch AS1 and/or the filter elements contained therein.

A novel mixed duplexer, which combines the B1- or B65-Tx band with a very broad Rx band (1427.9-1510.9 MHz), which covers the Rx bands of band 11, band 21, and B32, is connected to the antenna switch AS1. Thus, the B1- or B65-Tx/B3-Rx/B32-Rx triplexer can be replaced by a simpler mixed B—or B65-Tx/B3-Rx duplexer. Despite this, at least the following downlink carrier aggregation cases are covered, which contain combinations of two bands from the cellular mid-band (plus other bands from the low-band and/or high-band):
a.) B1/B65+B3 CA
b.) B1/B65+B32 CA
c.) B3+B32 CA
d.) B1/B65+B11 CA
e.) B1/B65+B21 CA
f.) B2/B25+B4/B66 CA

It is also possible to replace the B1-(or B65-)Tx/B(11+21+32)-Rx duplexer with a B1- or B65-)Tx/B3-Rx/B(11+21+32)-Rx triplexer. Then, the mixed B1- or B65-Tx/B3-Rx duplexer can be omitted.

In addition to the aforementioned CA combinations of two bands from the mid-band, the following combination of three bands from the cellular mid-band is also possible, which of course can be combined with yet other bands from the low-band and/or high-band:
g.) B1+B3+B32 CA

Even the exemplary embodiment according to FIG. 15C does not differ from the embodiments according to FIGS. 13, 14, 15A, and 15B, with the exception of the band channels connected to the first antenna switch AS1 and/or the filter elements contained therein. This results in the following differences, as compared to the exemplary embodiment according to FIG. 15B:

The B3-Tx/B3-Rx/B32-Rx triplexer is split into a normal B3-Tx/B3-Rx duplexer, and a B32-Rx individual filter or the triplexer is replaced by said filter elements, each of which has a phase shift circuit connected upstream. The B3 duplexer and the B32 filter are connected only as needed. In this case, the antenna switch AS1 must then support a state in which the B3 duplexer and the B32 filter are simultaneously connected to the input of the antenna switch AS1. In this state, the phase shifters are used to ensure the counter-band impedances (i.e., the impedance of the respective filter/duplexer in the respective counter-band), such that linking is possible with minor insertion loss.

In addition, the antenna switch AS1 can connect the B3 duplexer and the B32 filter individually to its input.

In this configuration, only the duplexers plus an individual filter are required in order to cover the previously mentioned CA cases a. through f. (as described in FIG. 15B).

The exemplary embodiment of a further front-end module is shown in FIG. 16. This embodiment also does not differ from the embodiments according to FIGS. 13 through 15, except for the antenna switches. These embodiments are characterized by two novel, micro-acoustic triplexers. A first combines band 1 TX with band 3 TX and band 3 RX. A second novel triplexer combines band 2 Tx (or band 25 Tx) with band 4 Tx (or band 66 Tx) with band 2 Rx (or band 25 RX).

Together with the extractor structure that extracts the Rx band of band 1, band 4, or band 66 from the signal path, these two triplexers enable uplink and downlink carrier aggregation mode for the CA combination of band 1 (or band 66) plus band 3, as well as for the CA combinations of band 2 (or band 25) plus band 4 (or band 66). Furthermore, it is possible to additionally combine one band from these two ranges thereto, because low-band and high-band ranges are diverted via other signal paths.

For example, it is thus possible to combine a low-band band with band 1 (band 65), band 3, and a high-band band, or to operate a low-band band with band 4 (band 66) and band 2 (band 25) together with a band from the high-band range. Exemplary band combinations are, for example, band 20/band 1/band 3/band 7 or band 12/band 4 (band 66)/band 2 (band 25)/band 30. All cases are suitable for an uplink and downlink carrier aggregation mode.

The exemplary embodiment shown in FIG. 17 differs only in the band channels connected to the first antenna switch AS1 or the filter elements contained therein. One band channel contains a novel, micro-acoustic quadplexer, which comprises the filter elements for band 1 TX/band 3 TX/band 3 RX, and band 32 RX. If said quadplexer is operated together with the extractor structure for band 66 or band 1 or band 4, an uplink and downlink carrier aggregation mode is possible for band 1, band 3, and band 32, wherein band 32 is a pure Rx band.

Because the low-band and high-band ranges are isolated, a band from the low-band range and the high-band range can, additionally, be combined with the proposed front-end module, e.g., a band combination of band 20/band 1/band 3/band 32/band 7. As shown in FIG. 17, the triplexer already described in FIG. 16 is necessary with band 2 TX/band 4 TX and band 2 RX, in addition to the novel quadplexer.

FIG. 18A shows an exemplary embodiment in which a front-end module according to the invention can be connected to a diversity antenna DAT and, together with the latter, can be designed for receive mode only. For the hardware components, including the antenna switches, the same arrangement can be used as already described in the exemplary embodiments with reference to FIGS. 13 through 17. However, in contrast to the previous embodiments, now, only pure receive filter elements are connected to the antenna switches, wherein the exemplary embodiment is characterized by novel diplexers, which are arranged behind the antenna switch of a diversity module and combine the receive filters of two different bands. With the first antenna switch AS1 for the mid-band range, a diplexed diversity receive filter is proposed in this respect, which combines filters for band 1 RX and band 32 RX. Together with the extractor arrangement for band 66/band 4/band 1, this diplexed diversity receive filter allows a pure receive carrier aggregation for band 1 with band 3 and band 32, which receive carrier aggregation can be carried out on the diversity antenna.

Since the low-band range and the high-band range of signal paths that are separated therefrom are separate, two additional bands—one each of the low-band range and one each of the high-band range—can respectively be operated in parallel thereto using the diversity antenna DAT. An exemplary band combination for the diversity mode comprises the bands 20, 1, 3, 32, and 7.

Another front-end module shown in FIG. 18B with an antenna connection for a diversity antenna DAT comprises, on the first antenna switch AS1, a new micro-acoustic, diplexed diversity receive filter, which combines filter elements for band 3 RX and band 21 RX. Together with an extractor arrangement, which can extract band 66/band 1/band 4, this diplexed diversity receive filter makes possible a pure receive carrier aggregation mode for bands 21, B3, and B1 on the diversity antenna. Because of separated low-band and high-band ranges, a receive band in the low-band and high-band range can respectively be combined therewith. It is then, for example, possible to equip the presented front-end module on the diversity antenna for carrier aggregation receive mode, which simultaneously supports bands 19, 21, 3, 1, and 7.

FIG. 19 shows another exemplary embodiment of a front-end module that can be connected to the diversity antenna DAT and which, once again, differs from the embodiments according to FIGS. 18A and 18B only in the filter elements connected to the first antenna switch AS1. In this respect, a micro-acoustic, triplexed diversity receive filter is connected to the first antenna switch AS1. This triplexed diversity receive filter comprises diversity receive filters for band 32/band 21/band 3. Together with an extractor arrangement for band 66/band 1/band 4, a pure receive carrier aggregation is made possible on the diversity antenna, so that a common receive mode in bands 21 and 3 and 1, or in bands 32 and 1, or in bands 1 and 11 is possible. Additionally, with a receive filter each of the low-band and high-band range, carrier aggregation modes for simultaneous operation of bands 20, 32, 3, 1, and 7 or, alternatively, B19, B21, B3, B1, and B7, for example, are possible on the diversity antenna DAT.

Whereas the front-end modules shown in the previous exemplary embodiments according to FIGS. 13 through 19 respectively comprise an extractor arrangement for band 66 or 4 or 1, front-end modules comprising an extractor arrangement for extracting band 40 (or band 30) are discussed below.

FIG. 20 shows a table with different possible combinations of a band-40 extractor arrangement with at least one additional extractor arrangement, which is, optionally, designed for GNSS, WLAN 2.4, band 66, band 32, or a band of the LMB.

FIG. 21 shows, by way of example, how combination 17, named in FIG. 20, of extractor arrangements for band 40 and GNSS can be divided across the extractor positions according to the schematic front-end module of FIG. 4. Whereas only one position A in front of the first diplexer DPX1 and a position F between the first diplexer and the second diplexer DPX2 is possible for the extractor arrangement for band 40, the extractor arrangement for GNSS can be arranged at almost all extractor positions.

FIG. 22 shows eight possibilities for how three different extractor arrangements for band 40, GNSS, and WLAN 2.4 can be distributed in a front-end module across the extractor positions according to FIG. 4. For such triple combinations, it is advantageous to arrange the band-40 extractor between the first and second diplexers DPX1/DPX2, i.e., for example, at position A.

With extractor combinations, which comprise band 40, the frequency ranges of the duplexers must be newly configured as a function of the band-40 extractor.

FIG. 23 shows four possibilities for how the passbands of the high-pass and low-pass filters of diplexers 1 and 2 can be configured. For all four possibilities a, b, c, and d, the low-pass filter of the first diplexer blocks frequencies above 960 MHz. The high-pass filter of the first diplexer DPX1 can have a passband that starts at 1425 MHz according to embodiment a, at 1447 MHz according to embodiment b, at 1559 MHz according to embodiment c, or at 1710 MHz according to embodiment d. In all embodiments, a through d, the low-pass filter of the second diplexer DPX2 blocks frequencies starting at 2170 MHz, while its high-pass filter allows frequencies ≥2496 MHz to pass.

FIG. 24 shows additional different possible arrangements for the extractor combination GNSS/WLAN 2.4/band 40 across the extractor positions according to FIG. 4.

A common feature of these proposed arrangements is that the extractor for band 40 is reasonably positioned at a position between the antenna connection and the first diplexer. The two remaining extractor arrangements can be distributed almost freely across the remaining extractor positions. For this distribution, the diplexers are also configured with respect to the frequency ranges according to FIG. 23.

FIG. 25 shows a front-end module with a diplexer and an extractor arrangement. A first antenna connection AT1 is connected to the first diplexer DPX1, which separates a low-band range up to 960 MHz via a low-pass filter. The high-pass filter of the first diplexer is, in particular, designed to separate a mid-band range of 1425 MHz to 2200 MHz. Provided between the high-pass filter and the first antenna switch AS1 is an extractor arrangement with which an extractor band corresponding to band 66 Rx or band 1, 4, and 65 Rx can be extracted from the signal path. The extractor arrangement EA1 is, optionally, provided with a bypass path, by means of which the extractor arrangement can be deactivated.

Arranged behind the extractor arrangement is the first antenna switch AS1, the outputs of which can be connected to two special triplexers. A first triplexer combines a TX filter for band 66 (band 1), an RX filter for band 3, and an RX filter for band 32. A second triplexer combines a TX filter for band 3 with an RX filter for band 32 and an RX filter for band 3.

The output of the antenna switch AS1 is, furthermore, connected to a mixed duplexer, which connects a TX filter for band 66/4 to an RX filter for band 2 (band 25). With this combination of a diplexer and the triplexers and duplexers connected to the first antenna switch AS1, the proposed front-end module can support a quadruple downlink carrier aggregation mode, in which bands B1/B65, B3, B7, and B32 are active in parallel. Another supported carrier aggregation mode for four bands comprises band 12 (or band 5 or band 29), band 2 (or band 25), band 66/4, and band 30, without quadplexers or hexaplexers being required for this purpose.

In addition to the first antenna connection AT1, which can be connected to a first antenna, the module comprises a second antenna connection AT2, which can be connected to a second antenna. The second antenna is designed for a frequency range of 2300 MHz to 2690 MHz and can optionally receive up to the 5 GHz range. A second diplexer DPX2, which separates a high-band range by means of a low-pass filter and forwards it to a second antenna switch AS2, is connected to the second antenna. This high-band is configured for a frequency range of 2300 MHz to 2690 MHz. It is also possible to connect a triplexer instead of the second diplexer to the second antenna. This triplexer can then be designed to also separate the ultrahigh-band and the 5 GHz range, in addition to the aforementioned high-band frequency range.

The output of the second antenna switch AS2 is, moreover, connected to traditional pure duplexers for band 30 and band 7.

At the high-pass filter of the second diplexer DPX2, a 3 GHz frequency range (optionally, up to 5 GHz) is separated. When this frequency range can be dispensed with, the second antenna switch can be connected directly to the second antenna connection AT2, and the second diplexer DPX2 can be dispensed with, just as the dashed line encloses these optional components.

FIG. 26 shows another exemplary embodiment of the invention, in which the front-end module comprises two antenna connections AT1 and AT2, which can be connected to two different antennae. The first antenna or the first antenna connection AT1 is designed to feed signals of 699 MHz to 2170 MHz. With the low-pass filter of a first diplexer DPX1, a low-band range between 699 MHz and 966 MHz is separated and forwarded to a third antenna switch AS3.

The high-pass filter of the first diplexer DPX1 separates a frequency range of 1425 MHz to 2025 MHz and forwards it to a first antenna switch AS1.

A second antenna connection, which can be connected to the second antenna, is designed to feed frequencies of 2300 MHz to 2690 MHz. Provided between the second antenna connection AT2 and a second antenna switch AS2 is an extractor arrangement that is designed to extract band 1/4/65/66 Rx. Pure duplexers for bands of the high-band range, e.g., duplexers for band 30 and band 7, are connected to the second antenna switch AS2.

The output of the first antenna switch AS1 is connected to two special triplexers, of which the first combines the following filter elements: a TX filter for band 1/65 with an RX filter for band 3 and an RX filter for band 32. The second triplexer combines a TX filter for band 3 with an RX filter for band 3 and an RX filter for band 32.

A mixed duplexer on the first antenna switch AS1 combines a TX filter for band 4 (band 66) with an RX filter for band 2 (band 25). A pure band-2 (band-25) duplexer is also connected to the first antenna switch AS1. With these special triplexers and the special duplexer, a quadruple downlink carrier aggregation mode is possible, in which the bands 1, 3, 7, and 32 can be operated in parallel. The bands 12 (or 5 or 29), 2, 4, and can, alternatively, be operated in parallel, without a cellular quadplexer or hexaplexer being required for this purpose.

In an optional expansion, a diplexer that separates the frequency range between 3 GHz and 5 GHz is provided between the second antenna connection AT2 and the first extractor arrangement EA1.

The front-end module according to FIG. 27 comprises two extractor arrangements that are designed to extract RX frequencies of band 66 and band 32.

The front-end module connects an antenna connection AT, via which can be fed in the frequencies of 699 MHz to 2690 MHz, to a first diplexer DPX1, which separates a low-band of 699 MHz to 960 MHz at the low-pass filter. Frequencies of 1425 MHz to 2690 MHz are channeled out at the output of the high-pass filter of the first diplexer DPX1. Within this signal path connected to the high-pass filter of the first diplexer DPX1, the two extractor arrangements, EA1 and EA2, are now arranged. Connected thereto is the second diplexer DPX2, which separates mid-band frequencies of 1425 MHz 15 to 2025 MHz at the low-pass filter and assigns them to a first antenna switch AS1. At the high-pass filter of the second diplexer DPX2, a high-band of 2300 MHz to 2690 MHz is channeled out and fed to a second antenna switch AS2.

Two novel, mixed duplexers are connected to the output of the first antenna switch AS1. A first mixed duplexer combines a TX filter for band 1/65 with an RX filter for band 3. A second mixed duplexer combines a TX filter for band 4/66 with an RX filter for band 2 (band 25). Pure duplexers for band 2 (band 25) and band 3 are, moreover, connected to the first antenna switch AS1.

Pure duplexers for bands of the high-band range, such as band 7 and/or band 30, are arranged at the output of the second antenna switch AS2. With such an arrangement, a quadruple downlink carrier aggregation mode, in which the bands 1, 3, 7, and 32 can be operated in parallel, is possible. Band 12 (or 5 or 29) can, alternatively, be operated in parallel together with band 2 and band 4 and band 30. This embodiment is characterized, in particular, in that no cellular quadplexers or hexaplexers are required.

If no bands of the low-band range are needed in the front-end module, or if the low-band range is operated via a second antenna, the first diplexer DPX1 can be dispensed with, and the first antenna connection AT can be connected directly to the two extractor arrangements.

FIG. 28 shows an exemplary embodiment, in which two different extractor arrangements for extracting band 66 (4/1/65) RX and band 32 RX are provided in a manner similar to that in FIG. 27, but in a different arrangement than in the example according to FIG. 27.

The antenna connection AT is connected to a first diplexer DPX1, which separates a low-band up to 960 MHz at the low-pass filter. Frequencies of 1425 MHz to 2690 MHz are channeled out at the high-pass filter and are forwarded to a second diplexer DPX2 via a first extractor arrangement EA1. The first extractor arrangement is, once again, designed for RX frequencies of band 66 (band 4/band 1/band 65).

In the second diplexer, a mid-band frequency range of 1425 MHz to 2025 MHz is separated at the low-pass filter and assigned to a first antenna switch AS1 via a second, but optional, extractor arrangement EA2 for frequencies between 1452 and 1496 MHz.

At the high-pass filter of the second duplexer DPX2, frequencies of 2300 MHz to 2690 MHz are forwarded to a second antenna switch AS2.

At the output of the first antenna switch AS1, pure duplexers for band 2 and band 3, as well as a mixed duplexer for band 1 TX/band 3 RX and band 4 TX/band 2 RX, are provided. With the help of this arrangement, it is possible to enable a quadruple downlink carrier aggregation mode of band 1, band 3, band 7, and band 32. Moreover, such a quadruple carrier aggregation mode for bands 12 (or 5 or 29), 2 (or 25), 4, and 30 is possible.

A cellular quadplexer or hexaplexer is not required for this quadruple carrier aggregation mode in any of the cases. Since the second proposed quadruple downlink carrier aggregation mode does not have to operate band 32, the extractor arrangement for band 32 can also be dispensed with. The first diplexer DPX1 can, optionally, also be omitted if frequencies of the low-band range are not required or are operated via another antenna.

Even though the invention has been described with reference to only a few specific exemplary embodiments, it is not limited to these embodiments. Front-end modules according to the invention can contain additional elements, which are not listed separately here. As proposed in FIG. 4, for example, the number of extractor arrangements can be increased in accordance with the number of extractable bands. The number of operable bands can be increased arbitrarily by connecting corresponding filter elements, wherein only filter elements for a given frequency range or for bands that are within this frequency range can, naturally, be assigned to an antenna switch for this frequency range.

Each extractor arrangement can, optionally, be provided with a bypass path, so that it can be activated or deactivated, depending upon the operating mode.

The filter elements at the output of the antenna switch, and the notch filters and bandpass filters in the extractor arrangements, comprise micro-acoustic resonators. The diplexers can be designed according to different technologies—preferably, integrated into an LTCC ceramic or a laminate—wherein the architecture according to the invention allows for a large diplexer spacing, which can be realized by simple means.

Even though only front-end modules according to the invention have been discussed, individual elements of such modules can, separately, also constitute inventions. These are, in particular, the special mixed duplexers or the triplexers for downlink and uplink carrier aggregation mode. Also, an extractor arrangement that can be activated or deactivated using an optional bypass path by means of a switch arranged therein can already be used in other architectures and exhibit advantageous effects.

It is also possible to divide the elements of the front-end modules described onto several substrates or carriers so that, strictly speaking, there are no longer modules, but arrangements, which must, however, also be considered to be subject matter according to the invention, and thus protected.

The invention furthermore also comprises more complex arrangements, to the extent that these comprise the structures described, but are provided with additional functions by connection to other elements and arrangements.

### LIST OF REFERENCE SYMBOLS

SP1 first signal path, connects
AT antenna connection and
DPX1 first diplexer
TP1,2 first and second partial paths at the diplexer output
EA1 first extractor arrangement with a
NF1 first notch filter with
EP1 first extractor path and
BP1 first bandpass filter arranged therein with a
LMB lower mid-band
UEB bypass path with a
SW switch arranged therein
AS antenna switch in a partial or signal path
LB low-band
MB mid-band
HB high-band
DAT diversity antenna, can be connected to
DRX diversity RX filter

1. Front-end module that is equipped for carrier aggregation mode,
with a first signal path (SP) that connects a first antenna connection (AT) to a first diplexer (DPX1) or a higher multiplexer,
with a notch filter (NF) that is connected to the diplexer and has a first stopband,
with a first extractor path (EP) that can be connected at a node arranged in the signal path between the antenna connection and the first notch filter,
with a bandpass filter (BP) for a first extractor band, which is arranged in the first extractor path (EP), wherein the notch filter and the bandpass filter form an extractor arrangement (EA),
wherein the diplexer separates a first and a second frequency range, which are separated by a first diplexer spacing, and respectively assigns them to a first partial path (TP1) or a second partial path (TP2),
wherein the stopband of the notch filter and the first extractor band overlap at least partially,
wherein the stopband is arranged between the first and second frequency ranges such that it does not overlap with any of the frequency ranges.

2. Front-end module according to claim 1,
in which a second diplexer (DPX2) or a higher multiplexer that separates at least a third frequency range from the first signal path and feeds it into a third partial path (TP3) is arranged in the first signal path (SP) between the first antenna connection (AT) and the notch filter (NF).

3. Front-end module according to one of the preceding claims,
in which the stopband completely overlaps the Rx band of band 66, or band 1, or band 4,
in which the bandpass filter (BP) is designed for the Rx band of band 66, or band 1, or band 4, or band 65,
in which the first frequency range comprises frequencies up to 1995 MHz or up to 2025 MHz,
in which the second frequency range comprises frequencies of higher than or equal to 2300 MHz,
so that the extractor path (EP) is designed to separate the Rx frequencies of band 66, or band 1, or band 4, or band 65.

4. Front-end module according to one of claims 1-3,
in which the stopband completely overlaps band 30 Rx and Tx and/or band 40,
in which the bandpass filter (BP) is designed for band 30 Rx and Tx and/or band 40,
in which the first frequency range comprises frequencies up to 2170 MHz or up to 2200 MHz,
in which the second frequency range comprises frequencies of higher than or equal to 2496 MHz,
in which the extractor path (EP) is designed to separate the Rx frequencies of band 30 and/or band 40.

5. Front-end module according to one of the preceding claims,
in which a second notch filter (NF) is arranged in the first signal path (SP) or in a partial path (TP) selected from the first, second, and third partial paths, wherein the notch filter has a second stopband,
in which an extractor path (EP) branches off from the first signal path or the respective partial path between the antenna connection (AT) and the at least one additional notch filter (NF), in which extractor path is arranged a bandpass filter (BP), the passband of which corresponds to a second extractor band, wherein the second stopband and the second extractor band at least partially overlap.

6. Front-end module according to one of the preceding claims,
in which two extractor arrangements (EA) are provided, which are designed to respectively extract one extractor band,
in which the first extractor band comprises the Rx band of band 66, or band 1, or band 4, or band 65,
in which the second extractor band is designed for frequencies that are selected from GNSS, WLAN 2.4, band 40, band 30, band 32, and LMB, wherein LMB comprises frequencies of 1425 to 1511 MHz.

7. Front-end module according to the preceding claim,
in which three extractor arrangements (EA1, EA2, EA3) are provided, which are designed to, together, extract three different extractor bands,
in which the first extractor band comprises the Rx band of band 66, or band 1, or band 4, or band 65,
in which the second and the third extractor bands are designed for different frequencies that are selected independently of each other from GNSS, WLAN 2.4, band 40, band 30, band 32, and LMB.

8. Front-end module according to one of the preceding claims,
in which each notch filter (NF) and each bandpass filter (BP) arranged in one of the extractor paths comprises micro-acoustic resonators that realize a SAW filter, a temperature-compensated SAW filter, or a BAW filter.

9. Front-end module according to one of the preceding claims,
in which diplexers (DPX) comprise low-pass, high-pass, or bandpass filters that are realized from L and C elements that are integrated into an LTCC ceramic or a laminate or realized as discrete L and C elements that are mounted on a carrier.

10. Front-end module according to one of the preceding claims,
in which each of the extractor arrangements (EA) can be bypassed using a bypass path (UEP),
in which a switch (SW) for opening or closing the bypass path is arranged in each bypass path.

11. Front-end module according to one of the preceding claims,
in which one of the partial paths (TP) is connected to the input of an antenna switch (AS),
in which an output of the antenna switch can optionally be connected via a corresponding switch position to a series of duplexers,
in which the duplexers comprise a mixed duplexer that combines an Rx filter for a first band and a Tx filter for a different second band,
in which an extractor band comprises Rx frequencies of the second band,
in which another duplexer is a pure duplexer that comprises a Tx filter and an associated Rx filter for the first band.

12. Front-end module according to the preceding claim,
in which a first mixed duplexer combines filters for B1 Tx with B3 Rx or B4 Tx with B2 Rx,
in which an extractor band is assigned to B4 Rx or B1 Rx.

13. Front-end module according to claim 11 or 12,
in which a mixed duplexer combines
B1 Tx with B3 Rx, or
B65 Tx with B3 Rx, or
B4 Tx with B2 Rx, or
B4 Tx with B25 Rx, or
B66 Tx with B2 Rx, or
B66 Tx with B25 Rx,
in which an extractor band is assigned to B4 Rx or B1 Rx or B66 Rx, in which pure duplexers are additionally provided, which combine the Rx band of the mixed duplexers listed above with the corresponding Tx band and which are selected from the duplexers for B3 Tx/B3 Rx, B2 Tx/B2 Rx, and B25 Tx and B25 Rx.

14. Front-end module according to one of claims 11-13,
in which an output of the antenna switch (AS) can be connected via a corresponding switch position to two triplexers,
in which one of the triplexers comprises a filter combination for B1 Tx/B3 Rx/B32 Rx or B65 Tx/B3 Rx/B32 Rx or a filter combination for B3 Tx/B3 Rx/B32 Rx,
in which an extractor band is assigned to B4 Rx or B1 Rx or B65 Rx.

15. Front-end module according to one of claims 11-14,
comprising a mixed duplexer that combines
B1 Tx/B(11+21)Rx, or
B1 Tx/B11 Rx, or
B1 Tx/B21 Rx,
in which an extractor band is assigned to B4 Rx or B1 Rx or B66 Rx,
in which a pure duplexer for B11 or B21 is also provided.

16. Front-end module according to one of claims 11-15,
in which the output of the antenna switch (AS) can be connected via a corresponding switch position to a triplexer and a duplexer,
in which the triplexer comprises a filter combination for B1 or B65 Tx/B3 Tx/B3 Rx or a filter combination for B2 or B25 Tx/B4 or B66 Rx/B2 or B25 Rx,
in which an extractor band is assigned to B4 Rx or B Rx or B66 Rx or B65 Rx.

17. Front-end module according to one of claims 11-16,
in which one of the outputs of the antenna switch (AS) can be connected via a corresponding switch position to a triplexer and/or a duplexer and a quadplexer,
in which the quadplexer comprises a filter combination for B1 or B65 Tx/B3 Tx/B3 Rx/B32 Rx,
in which an extractor band is assigned to B4 Rx or B1 Rx or B66 Rx.

18. Front-end module according to one of claims 11-17,
with a pure receive path that can be connected to a diversity antenna (DAT), with an extractor arrangement (EA), which branches off an extractor path (EP) from a pure receive path, wherein the extractor band is assigned to B4 Rx, B1 Rx, B65 Rx, or B66 Rx,
in which a diplexer (DPX) is arranged in the pure receive path, which diplexer divides the pure receive path into two pure partial receive paths, which are respectively assigned to a mid-band (MB) and a high-band (HB) range, in which a mixed diversity diplexer that has a filter combination for B3 Rx/B21 Rx or B3 Rx/B32 Rx is arranged in the partial receive path for mid-band.

19. Front-end module according to the preceding claim,
in which another diplexer (DPX) or higher multiplexer that branches another partial path (TP) for a frequency range off from the pure receive path is arranged between the diversity antenna (DAT) and the extractor arrangement (EA).

20. Front-end module according to one of the preceding claims,
with a pure receive path that can be connected to a diversity antenna (DAT),
with an extractor arrangement (EA), which branches off an extractor path (EP) from a pure receive path, wherein the extractor band is assigned to B4 Rx, B1 Rx, B65 Rx, or B66 Rx,
in which a diplexer (DPX) is arranged in the pure receive path, which diplexer divides the pure receive path into two pure partial receive paths, which are respectively assigned to a mid-band and a high-band range,
in which a mixed diversity triplexer that comprises a filter combination for B32 Rx/B21 Rx/B3 Rx is arranged in the partial receive path for mid-band.

21. Front-end module according to one of the preceding claims,
in which two extractor arrangements (EA) are provided, which are designed to respectively extract one extractor band,
in which the first extractor band comprises band 30 Rx and Tx and/or band 40,
in which the second extractor band is designed for frequencies that are selected from GNSS, WLAN 2.4, band 66 Rx, band 32 Rx, and LMB,
wherein LMB comprises frequencies of 1425 to 1511 MHz.

22. Front-end module according to one of the preceding claims,
comprising three extractor arrangements (EA), wherein one of the extractor arrangements (EA) is designed for band 30 and/or band 40.

23. Front-end module according to one of the preceding claims,
in which a mixed duplexer with a filter combination for bands B1 or B65 Tx/B(11+21+32) Rx is provided.

24. Front-end module according to one of the preceding claims,
in which a mixed triplexer that can separate bands B1 or B65 Tx/B3 Rx/B(11+21+32) Rx and respectively assign them to a band channel is provided.
